(19) United States
(12) Patent Application Publication
(10) Pub. No.: US 2026/0169384 A1
(43) Pub. Date: Jun. 18, 2026

(54) POLYMER, RESIST COMPOSITION INCLUDING THE SAME, AND PATTERN FORMATION METHOD USING THE RESIST COMPOSITION

(71) Applicant: Samsung Electronics Co., Ltd., Suwon-si (KR)

(72) Inventors: Kyuhyun IM, Suwon-si (KR); Minsang KIM, Suwon-si (KR); Hyunseok CHOI, Suwon-si (KR); Yoonhyun KWAK, Suwon-si (KR); Youngmin NAM, Suwon-si (KR); Jaejun LEE, Suwon-si (KR)

(73) Assignee: Samsung Electronics Co., Ltd., Suwon-si (KR)

(21) Appl. No.: 19/191,234

(22) Filed: Apr. 28, 2025

(30) Foreign Application Priority Data
Dec. 12, 2024 (KR) 10-2024-0185073

(51) Int. Cl. G03F 7/039; C08F 220/18; C08F 220/30

(52) U.S. Cl. CPC G03F 7/039; C08F 220/1807; C08F 220/301

(57) ABSTRACT

Provided are a polymer including a first repeating unit represented by Formula 1, a second repeating unit represented by Formula 2, and a third repeating unit represented by Formula 3, a resist composition including the polymer, and a pattern formation method using the resist composition:

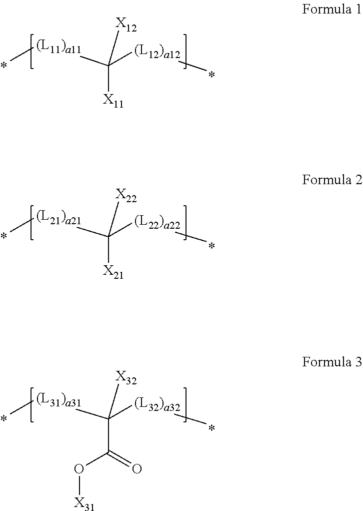

wherein L₁₁, L₁₂, L₂₁, L₂₂, L₃₁, L₃₂, a₁₁, a₁₂, a₂₁, a₂₂, a₃₁, a₃₂, X₁₁, X₁₂, X₂₁, X₂₂, X₃₁ and X₃₂ in Formulas 1 to 3 are described in the specification.

### CROSS-REFERENCE TO RELATED APPLICATION

This application is based on and claims priority under 35 USC § 119 to Korean Patent Application No. 10-2024-0185073, filed on Dec. 12, 2024, in the Korean Intellectual Property Office, the disclosure of which is incorporated by reference herein in its entirety.

### BACKGROUND

### 1. Field

The disclosure relates to a polymer, a resist composition including the same, and/or a pattern formation method using the resist composition.

### 2. Description of the Related Art

In semiconductor manufacturing, resists may have physical properties that change in response to light and resists may be used to form fine patterns. Among these resists, chemically amplified resists may be used. In chemically amplified resists, an acid may be formed through a reaction between light and a photoacid generator, the acid may react with a base resin again to change the solubility of the base resin with respect to a developer, thereby enabling patterning.

In particular, when using high-energy rays with relatively very high energy, such as EUV, the number of may be significantly smaller even when light of the same energy is irradiated. Accordingly, the may be a need for resist compositions that may be used effectively at low dosages and may provide improved sensitivity, improved resolution and/or improved defect reduction.

### SUMMARY

Provided are a polymer capable of providing improved sensitivity and/or improved resolution, a resist composition including the polymer, and/or a pattern formation method using the resist composition.

Additional aspects will be set forth in part in the description which follows and, in part, will be apparent from the description, or may be learned by practice of the presented embodiments of the disclosure.

According to an embodiment of the disclosure, a polymer may include a first repeating unit represented by Formula 1, a second repeating unit represented by Formula 2, and a third repeating unit represented by Formula 3:

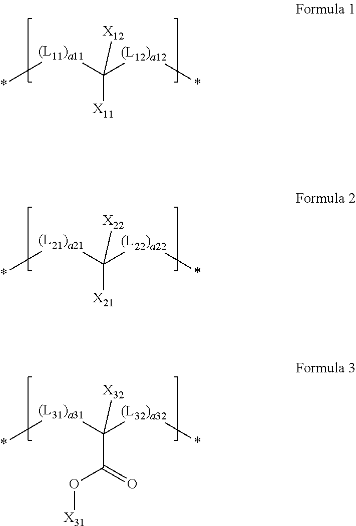

wherein in Formulae 1 to 3,
L₁₁ and L₁₂ each independently may be a single bond, O, S, C(═O), C(═O)O, OC(═O), C(═O)NR₁₁; NR₁₁C(═O), S(═O), S(═O)₂, S(═O)₂O, OS(═O)₂, or a linear, branched or cyclic C₁-C₃₀ divalent hydrocarbon group optionally including a heteroatom,
L₂₁ and L₂₂ each independently may be a single bond, O, S, C(═O), C(═O)O, OC(═O), C(═O)NR₂₁, NR₂₁C(═O), S(═O), S(═O)₂, S(═O)₂O, OS(═O)₂, or a linear, branched or cyclic C₁-C₃₀ divalent hydrocarbon group optionally including a heteroatom,
L₃₁ and L₃₂ each independently may be a single bond, O, S, C(═O), C(═O)O, OC(═O), C(═O)NR₃₁, NR₃₁C(═O), S(═O), S(═O)₂, S(═O)₂O, OS(═O)₂, or a linear, branched or cyclic C₁-C₃₀ divalent hydrocarbon group optionally including a heteroatom,
a₁₁, a₁₂, a₂₁, a₂₂, a₃₁ and a₃₂ each independently may be an integer from 1 to 4,
X₁₁ may be CN, C(═O)R₁₂, C(═O)OR₁₂, C(═O)SR₁₂, or C(═O)NR₁₂R₁₃,
X₁₂ may be an electron withdrawing group,
X₂₁ may be a substituted or unsubstituted C₆-C₃₀ aryl group,
X₃₁ may be a substituted or unsubstituted C₁₀-C₂₀ aryl group,
R₁₁ to R₁₃, R₂₁, R₃₁, X₂₂ and X₃₂ each independently may be hydrogen, deuterium, a halogen atom, a cyano group, or a linear, branched or cyclic C₁-C₃₀ monovalent hydrocarbon group optionally including a heteroatom, and
* may be a bonding site with a neighboring atom.

According to another embodiment of the disclosure, a resist composition may include the polymer and a solvent.

According to another embodiment of the disclosure, a pattern formation method may include applying the resist composition onto a substrate to form a resist film, exposing at least a portion of the resist film to high-energy rays to provide an exposed resist film, and developing the exposed resist film using a developer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a method of forming a pattern, according to an embodiment;

FIGS. 2A to 2C are cross-sectional side views showing a method of forming a pattern, according to an embodiment;

FIGS. 3A to 3E are cross-sectional side views showing a method of forming a patterning structure, according to an embodiment;

FIGS. 4A to 4E are cross-sectional side views showing a method of forming a semiconductor device, according to an embodiment;

FIG. 5 is a graph showing thicknesses of thin films after development according to the doses of Examples 2-1 to 2-4;

FIG. 6 is a graph showing the thickness of a thin film after development according to the doses of Comparative Example 2-1; and

FIGS. 7A to 7D are pattern images of Examples 3-1 to 3-3 and Comparative Example 3-1.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As the disclosure allows for various changes and numerous embodiments, particular embodiments will be illustrated in the drawings and described in detail in the written description. However, this is not intended to limit the disclosure to particular modes of practice, and it is to be appreciated that all modifications, equivalents, and substitutes that do not depart from the spirit and technical scope of the disclosure are encompassed in the disclosure. In describing the disclosure, when it is determined that the specific description of the known related art unnecessarily obscures the gist of the disclosure, the detailed description thereof will be omitted.

Although the terms “first”, “second”, “third”, and the like may be used herein to describe various elements, these terms are only used to distinguish one element from another and the order, type, or the like of the elements are not limited thereby.

A portion of a layer, film, region, plate, or the like described as being “on” or “above” another portion as used herein, it may include not only the meaning of immediately on/under/to the left/to the right in a contact manner, but also the meaning of on/under/to the left/to the right in a non-contact manner.

An expression used in the singular encompasses the expression of the plural, unless it has a clearly different meaning in the context. Unless explicitly described to the contrary, it is to be understood that the terms such as “including” and “having” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

The expression “Cₓ-C_{y}” used herein refers to the case where the number of carbon atoms constituting a substituent is in a range of x to y. For example, the expression “C₁-C₆” refers to the case where the number of carbon atoms constituting a substituent is in a range of 1 to 6, and the expression “C₆-C₂₀” refers to the case where the number of carbon atoms constituting a substituent is in a range of 6 to 20.

The term “monovalent hydrocarbon group” used herein refers to a monovalent residue derived from an organic compound including carbon and hydrogen or a derivative thereof, and specific examples thereof include a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (e.g., an allyl group); a monovalent unsaturated cycloaliphatic hydrocarbon group (a cycloalkenyl group) (e.g., 3-cyclohexenyl); an aryl group (e. g., a phenyl group, a 1-naphthyl group, and a 2-naphthyl group); an arylalkyl group (e. g., a benzyl group and a diphenylmethyl group); a heteroatom-including monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or a combination thereof. Additionally, some of hydrogens in these groups may be substituted with a moiety including a heteroatom such as oxygen, sulfur, nitrogen, phosphorous or halogen atoms, or some of carbons in these groups may be replaced by a moiety including a heteroatom such as oxygen, sulfur, nitrogen, or phosphorous, and thus these groups may include a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, or a carboxylic anhydride moiety.

The term “divalent hydrocarbon group” as used herein is a divalent residue and refers to a system in which any one hydrogen atom of the monovalent hydrocarbon group is replaced by a bonding site with a neighboring atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

The term “alkyl group” as used herein refers to a linear or branched saturated aliphatic monovalent hydrocarbon group, and examples thereof may include a methyl group, an ethyl group, a propyl group, an isobutyl group, a sec-butyl group, a tert-butyl group, a pentyl group, an iso-amyl group, and a hexyl group. The term “alkylene group” as used herein refers to a linear or branched saturated aliphatic divalent hydrocarbon group, and examples thereof may include a methylene group, an ethylene group, a propylene group, a butylene group, and an isobutylene group.

The term “halogenated alkyl group” as used herein refers to a group in which one or more substituents of an alkyl group are substituted with a halogen atom, and examples thereof may include CF₃. The halogen atom may be F, Cl, Br or I.

The term “alkoxy group” as used herein refers to a monovalent group represented by Formula —OA₁₀₁, wherein A₁₀₁ is an alkyl group. Specific examples thereof may include a methoxy group, an ethoxy group, an isopropyloxy group, and the like.

The term “alkylthio group” as used herein refers to a monovalent group represented by Formula —SA₁₀₁, wherein A₁₀₁ is an alkyl group.

The term “halogenated alkoxy group” as used herein refers to a group in which one or more hydrogen atoms of an alkoxy group are substituted with a halogen atom, and specific examples thereof may include —OCF₃ and the like.

The term “halogenated alkylthio group” as used herein refers to a group in which one or more hydrogen atoms of an alkylthio group are substituted with a halogen atom, and specific examples thereof may include —SCF₃ and the like.

The term “cycloalkyl group” as used herein refers to a monovalent saturated hydrocarbon cyclic group, and specific examples thereof may include monocyclic groups, such as a cyclopropyl group, a cyclobutyl group, a cyclopentyl group, a cyclohexyl group, and a cycloheptyl group, and polycyclic condensed cyclic groups, such as a norbornyl group and an adamantyl group. The term “cycloalkylene group” as used herein refers to a divalent saturated hydrocarbon cyclic group, and specific examples thereof may include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group represented by Formula —OA₁₀₂, wherein A₁₀₂ is a cycloalkyl group. Specific examples thereof may include a cyclopropoxy group, a cyclobutoxy group, and the like.

The term “cycloalkylthio group” as used herein refers to a monovalent group represented by Formula —SA₁₀₂, where A₁₀₂ is a cycloalkyl group.

The term “heterocycloalkyl group” as used herein refers to a group in which some carbon atoms of the cycloalkyl group are substituted with a moiety including a heteroatom, such as oxygen, sulfur, or nitrogen, and the heterocycloalkyl group may specifically include an ether bond, an ester bond, a sulfonate bond, a carbonate, a lactone ring, a sultone ring, or a carboxylic anhydride moiety. The term “heterocycloalkylene group” as used herein refers to a group in which some carbon atoms of the cycloalkylene group are substituted with a moiety including a heteroatom such as oxygen, sulfur, or nitrogen.

The term “heterocycloalkoxy group” as used herein refers to a monovalent group represented by Formula —OA₁₀₃, wherein A₁₀₃ is a heterocycloalkyl group.

The term “heterocycloalkylthio group” as used herein refers to a monovalent group represented by Formula of —SA₁₀₃, wherein A₁₀₃ is a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “cycloalkenyl group” as used herein refers to a monovalent unsaturated hydrocarbon cyclic group including at least one carbon-carbon double bond. The term “cycloalkenylene group” as used herein refers to a divalent unsaturated hydrocarbon cyclic group including at least one carbon-carbon double bond.

The term “heterocycloalkenyl group” as used herein refers to a group in which some carbon atoms of the cycloalkenyl group are substituted with a moiety including a heteroatom such as oxygen, sulfur, or nitrogen. The term “heterocycloalkenylene group” as used herein refers to a group in which some carbon atoms of the cycloalkenylene group are substituted with a moiety including a heteroatom such as oxygen, sulfur, or nitrogen.

The term “alkynyl group” as used herein refers to a linear or branched monovalent unsaturated aliphatic hydrocarbon group including one or more carbon-carbon triple bonds.

The term “aryl group” as used herein refers to a monovalent group including a carbocyclic aromatic system, and examples thereof include a phenyl group, a naphthyl group, an anthracenyl group, a phenanthrenyl group, a pyrenyl group, and a chrysenyl group. The term “arylene group” as used herein refers to a divalent group including a carbocyclic aromatic system.

The term “aryloxy group” as used herein refers to a monovalent group represented by Formula —OA₁₀₄, where A₁₀₄ is an aryl group.

The term “arylthio group” as used herein refers to a monovalent group represented by Formula —SA₁₀₄, where A₁₀₄ is an aryl group.

The term “heteroaryl group” as used herein refers to a monovalent group including a heterocyclic aromatic system, and examples thereof include a pyridinyl group, a pyrimidinyl group, and a pyrazinyl group. The term “heteroarylene group” as used herein refers to a divalent group including a heterocyclic aromatic system.

The term “heteroaryloxy group” as used herein refers to a monovalent group represented by Formula —OA₁₀₅, where A₁₀₅ is a heteroaryl group.

The term “heteroarylthio group” as used herein refers to a monovalent group represented by Formula —SA₁₀₅, where A₁₀₅ is a heteroaryl group.

The term “arylalkyl group” as used herein refers to a group in which a monovalent group having a carbocyclic aromatic system is substituted on an alkyl group, and specific examples include a benzyl group, a diphenylmethyl group, and the like.

The term “heteroarylalkyl group” as used herein refers to a group in which a monovalent group having a heterocyclic aromatic system is substituted on an alkyl group.

The term “heterocyclic group” as used herein refers to a monocyclic or polycyclic group having 1 to 60 carbon atoms and containing at least one heteroatom, and is a group including monovalent, divalent, trivalent, etc.

The term “substituent” as used herein includes deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group; and

a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and C₁-C₂₀ heteroarylthio group, each being substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, or a combination thereof; or a combination thereof.

Hereinafter, embodiments will be described in detail with reference to the accompanying drawings, wherein like reference numerals denote the same or substantially the same corresponding components throughout the drawings, and a redundant description thereof will be omitted. In the drawings, thicknesses of various layers and regions are enlarged for clarity. Also, in the drawings, the thicknesses of some layers and regions are exaggerated for convenience of description. Meanwhile, embodiments set forth hereinafter are merely for illustrative purposes, and various changes may be made therein.

### [Polymer]

A polymer according to embodiments include a first repeating unit represented by Formula 1, a second repeating unit represented by Formula 2, and a third repeating unit represented by Formula 3:

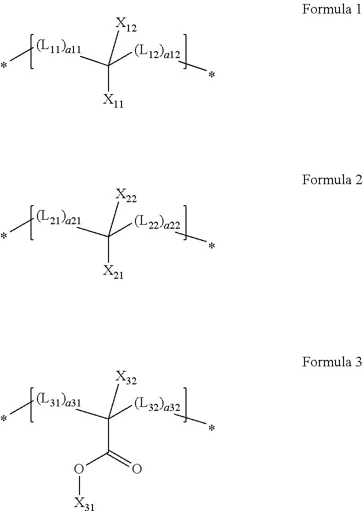

wherein in Formulae 1 to 3,
L₁₁ and L₁₂ each independently may be a single bond; O; S; C(═O); C(═O)O; OC(═O); C(═O)NR₁₁; NR₁₁C(═O); S(═O); S(═O)₂; S(═O)₂O; OS(═O)₂, or a linear, branched or cyclic C₁-C₃₀ divalent hydrocarbon group optionally including a heteroatom,
L₂₁ and L₂₂ each independently may be a single bond; O; S; C(═O); C(═O)O; OC(═O); C(═O)NR₂₁; NR₂₁C(═O); S(═O); S(═O)₂; S(═O)₂O; OS(═O)₂, or a linear, branched or cyclic C₁-C₃₀ divalent hydrocarbon group optionally including a heteroatom,
L₃₁ and L₃₂ each independently may be a single bond; O; S; C(═O); C(═O)O; OC(═O); C(═O)NR₃₁; NR₃₁C(═O); S(═O); S(═O)₂; S(═O)₂O; OS(═O)₂, or a linear, branched or cyclic C₁-C₃₀ divalent hydrocarbon group optionally including a heteroatom,
a₁₁, a₁₂, a₂₁, a₂₂, a₃₁ and a₃₂ each independently may be an integer from 1 to 4,
X₁₁ may be CN, C(═O)R₁₂, C(═O)OR₁₂, C(═O)SR₁₂, or C(═O)NR₁₂R₁₃,
X₁₂ may be an electron withdrawing group,
X₂₁ may be a substituted or unsubstituted C₆-C₃₀ aryl group,
X₃₁ may be a substituted or unsubstituted C₁₀-C₂₀ aryl group,
R₁₁ to R₁₃, R₂₁, R₃₁, X₂₂ and X₃₂ each independently may be hydrogen; deuterium; a halogen; a cyano group; or a linear, branched or cyclic C₁-C₃₀ monovalent hydrocarbon group optionally including a heteroatom, and
* may be a bonding site with a neighboring atom.

For example, in Formulae 1 to 3, L₁₁, L₁₂, L₂₁, L₂₂, L₃₁ and L₃₂ may each independently be: a single bond; O; S; C(═O); C(═O)O; OC(═O); C(═O)NH; NHC(═O); S(═O); S(═O)₂; S(═O)₂O; OS(═O)₂; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

Specifically, in Formulae 1 to 3, L₁₁, L₁₂, L₂₁, L₂₂, L₃₁ and L₃₂ may each independently be selected from: a single bond; O; C(═O); C(═O)O; OC(═O); C(═O)NH; NHC(═O); and a C₁-C₂₀ alkylene group, a C₃-C₂₀ cycloalkylene group, a C₃-C₂₀ heterocycloalkylene group, a C₂-C₂₀ alkenylene group, a C₃-C₂₀ cycloalkenylene group, a C₃-C₂₀ heterocycloalkenylene group, a C₆-C₂₀ arylene group, and a C₁-C₂₀ heteroarylene group, each unsubstituted or substituted with deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or a combination thereof.

More specifically, in Formulae 1 to 3, L₁₁, L₁₂, L₂₁, L₂₂, L₃₁ and L₃₂ may each independently be selected from: a single bond; O; C(═O); C(═O)O; OC(═O); C(═O)NH; NHC(═O); and a C₁-C₂₀ alkylene group, a C₃-C₂₀ cycloalkylene group, a C₃-C₂₀ heterocycloalkylene group, a phenylene group and a naphthylene group, each unsubstituted or substituted with deuterium, a halogen atom, a C₁-C₂₀ alkyl group, a C₁-C₂₀ halogenated alkyl group, a C₁-C₂₀ alkoxy group, a phenyl group, a naphthyl group, or a combination thereof.

In particular, in Formulae 1 to 3, L₁₁, L₁₂, L₂₁, L₂₂, L₃₁ and L₃₂ may each independently be selected from a single bond; O; C(═O); C(═O)O; OC(═O); and a C₁-C₁a alkylene group unsubstituted or substituted with deuterium, a halogen atom, a C₁-C₂₀ alkyl group, a C₁-C₂₀ halogenated alkyl group, a C₁-C₂₀ alkoxy group, or a combination thereof.

In Formulae 1 to 3, all, a₁₂, a₂₁, a₂₂, a₃₁ and a₃₂ represent the number of repetitions of L₁₁, L₁₂, L₂₁, L₂₂, L₃₁ and L₃₂, respectively.

For example, in Formulae 1 to 3, all, a₁₂, a₂₁, a₂₂, a₃₁ and a₃₂ may each independently be an integer from 1 to 3.

Specifically, in Formulae 1 to 3, all, a₁₂, a₂₁, a₂₂, a₃₁ and a₃₂ may each independently be 1.

For example, in Formula 1, one of (L₁₁)ₐ₁₁ and (L₁₂)ₐ₁₂ may be a single bond, and the other may be selected from 0; C(═O); C(═O)O; OC(═O); and a C₁-C₁ alkylene group unsubstituted or substituted with deuterium, a halogen atom, a C₁-C₂₀ alkyl group, a C₁-C₂₀ halogenated alkyl group, a C₁-C₂₀ alkoxy group, or a combination thereof.

For example, in Formula 2, one of (L₂₁)ₐ₂₁ and (L₂₂)ₐ₂₂ may be a single bond, and the other may be selected from 0; C(═O); C(═O)O; OC(═O); and a C₁-C₁ alkylene group unsubstituted or substituted with deuterium, a halogen atom, a C₁-C₂₀ alkyl group, a C₁-C₂₀ halogenated alkyl group, a C₁-C₂₀ alkoxy group, or a combination thereof.

For example, in Formula 3, one of (L₃₁)ₐ₃₁ and (L₃₂)ₐ₃₂ may be a single bond, and the other may be selected from 0; C(═O); C(═O)O; OC(═O); and a C₁-C₁ alkylene group unsubstituted or substituted with deuterium, a halogen atom, a C₁-C₂₀ alkyl group, a C₁-C₂₀ halogenated alkyl group, a C₁-C₂₀ alkoxy group, or a combination thereof.

For example, in Formula 1, X₁₁ may be represented by any one of Formulae 4-1 to 4-4:

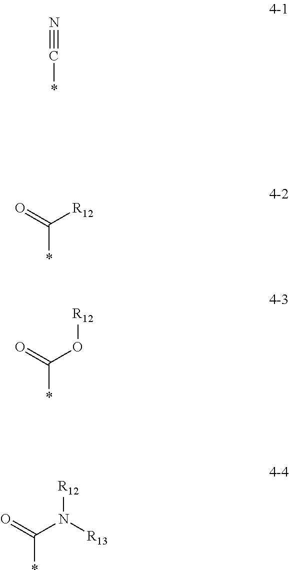

wherein in Formulae 4-1 to 4-4,
R₁₂ and R₁₃ refer to the description in Formula 1, respectively, and
* may be a bonding site with a neighboring atom.

Specifically, in Formula 1, X₁₁ may be represented by Formula 4-3.

For example, in Formula 1, X₁₂ may be selected from a halogen atom; a cyano group; a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each substituted with a halogen atom, a cyano group, a C₁-C₂₀ halogenated alkyl group, or a combination thereof; and SO₃Rₓ, and

Rₓ may be selected from a C₁-C₁ alkyl group and a C₆-C₁₀ aryl group, each unsubstituted or substituted with deuterium, a halogen atom, a cyano group, a C₁-C₂₀ alkyl group, a C₁-C₂₀ halogenated alkyl group, a C₁-C₂₀ alkoxy group, or a combination thereof.

Specifically, in Formula 1, X₁₂ may be selected from a halogen atom; a cyano group; a C₁-C₂₀ alkyl group and a C₆-C₂₀ aryl group, each substituted with a halogen, a cyano group, a C₁-C₂₀ halogenated alkyl group, or a combination thereof; and SO₃Rₓ, and

Rₓ may be selected from a C₁-C₁₀ alkyl group and a C₆-C₁₀ aryl group, each unsubstituted or substituted with deuterium, a halogen atom, a C₁-C₂₀ alkyl group, a C₁-C₂₀ halogenated alkyl group, or a combination thereof.

More specifically, in Formula 1, X₁₂ may be F, CH₂F, CHF₂, CF₃, CHFCH₃, CHFCH₂F, CHFCHF₂, CHFCF₃, CH₂CF₃, CF₂CH₃, CF₂CH₂F, CF₂CHF₂, CF₂CF₃, Cl, CH₂C₁, CHCl₂, CCl₃, CHClCH₃, CHClCH₂Cl, CHClCHCl₂, CHClCCl₃, CH₂CCl₃, CCl₂CH₃, CCl₂CH₂Cl, CCl₂CHCl₂, CCl₂CCl₃, C₆F₆, CCl₆, CN, SO₃CH₃, SO₃CF₃, or SO₃C₆H₅(CH₃).

For example, in Formula 2, X₂₁ may be selected from a C₆-C₂₀ aryl group unsubstituted or substituted with deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylate anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or a combination thereof.

Specifically, in Formula 2, X₂₁ may be selected from a C₆-C₂₀ aryl group unsubstituted or substituted with deuterium, a halogen atom, a cyano group, a hydroxyl group, an amino group, a carboxylate group, a thiol group, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or a combination thereof.

More specifically, in Formula 2, X₂₁ may be selected from a phenyl group and a naphthyl group, each unsubstituted or substituted with deuterium, a halogen atom, a cyano group, a hydroxyl group, a C₁-C₁₀ alkyl group, a C₁-C₁₀ halogenated alkyl group, a C¹-C₁₀ alkoxy group, a C₃-C₁₀ cycloalkyl group, a C₃-C₁₀ cycloalkoxy group, a phenyl group, a naphthyl group, or a combination thereof.

For example, in Formula 3, X₃₁ may be represented by any one of Formulae 5-1 to 5-26:

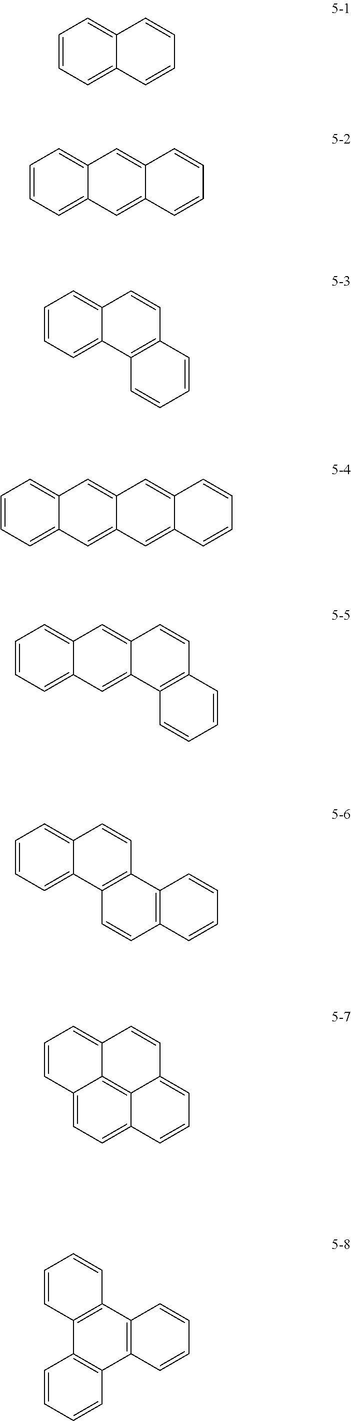

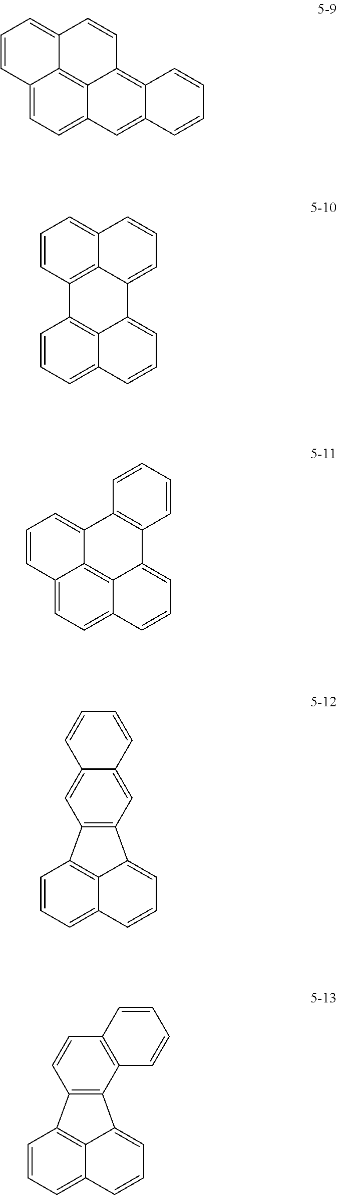

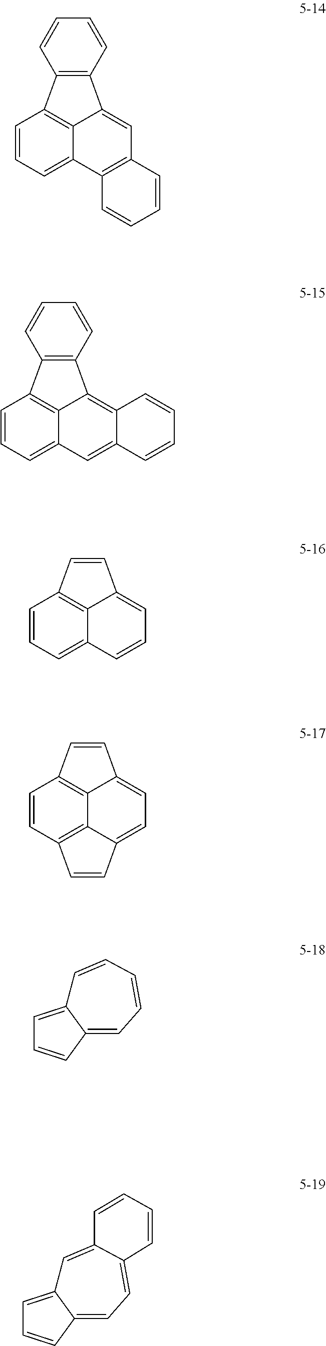

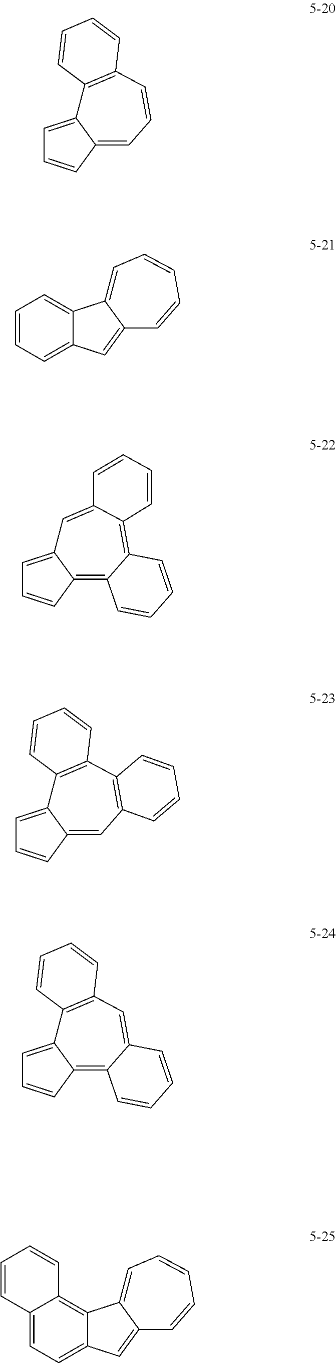

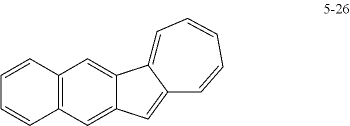 [SMILES: c1ccc2cc3cc4ccccc4cc3c-2cc1]

wherein in Formulae 5-1 to 5-26,
one carbon atom may be bonded to O in the Formula 3, and
the remaining carbon atoms may be each optionally substituted with hydrogen, deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylate anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or a combination thereof.

Specifically, in Formula 3, X₃₁ may be represented by any one of the following Formulae 6-1 to 6-10:

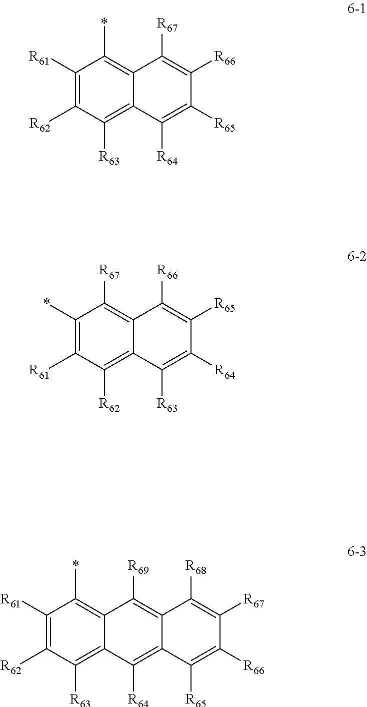

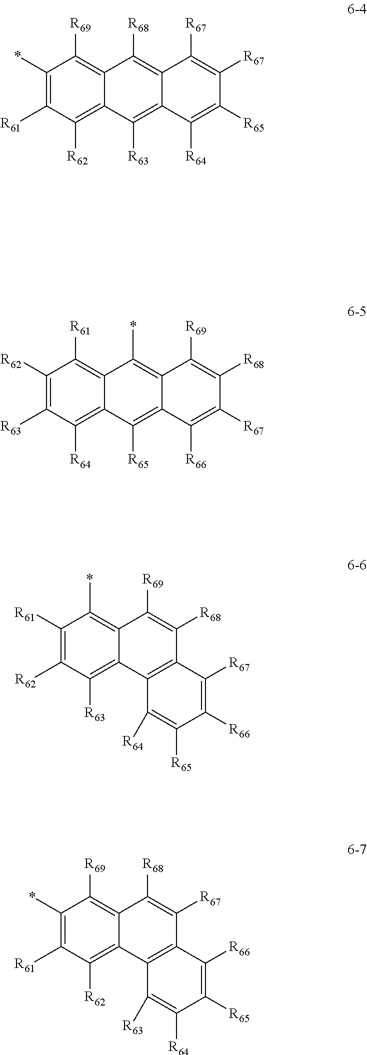

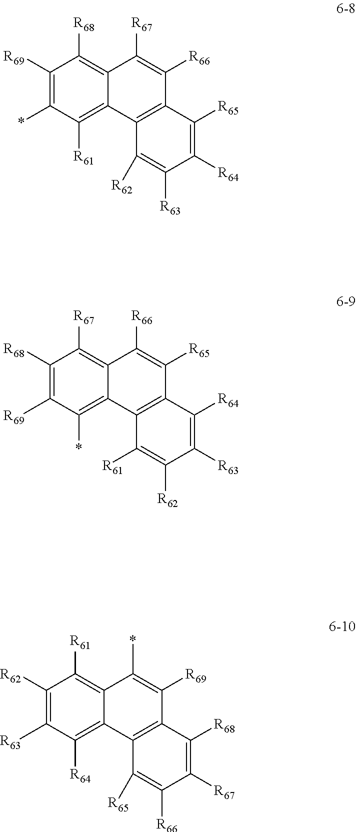

wherein in Formulae 6-1 to 6-10,
R₆₁ to R₆₉ may each independently be selected from hydrogen, deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylate anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, and a C₆-C₂₀ aryl group, and
* may be a binding site with O in Formula 3.

For example, in Formulae 6-1 to 6-10, R₆₁ to R₆₉ may each independently be selected from hydrogen, deuterium, a halogen atom, a hydroxyl group, a C₁-C₂₀ alkyl group, a C₁-C₂₀ halogenated alkyl group, and a C₁-C₂₀ alkoxy group.

For example, in Formulae 1 to 3, R₁₁ to R₁₃, R₂₁, R₃₁, X₂₂ and X₃₂ may each independently be selected from hydrogen; deuterium; and a C₁-C₂₀ alkyl group, a C₃-C₂₀ cycloalkyl group and a C₆-C₂₀ aryl group, each unsubstituted or substituted with deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylate anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or a combination thereof.

Specifically, in Formulae 1 to 3, R₁₁ to R₁₃, R₂₁, R₃₁, X₂₂ and X₃₂ may each independently be selected from hydrogen; deuterium; and a C₁-C₂₀ alkyl group and a C₆-C₂₀ aryl group, each unsubstituted or substituted with deuterium, a halogen atom, a cyano group, a C₁-C₂₀ alkyl group, a C₆-C₂₀ aryl group, or a combination thereof.

More specifically, in Formulae 1 to 3, R₁₁ to R₁₃, R₂₁, R₃₁, X₂₂ and X₃₂ may each independently be selected from hydrogen; deuterium; and a C₁-C₁₀ alkyl group and a C₆-C₁₀ aryl group, each unsubstituted or substituted with deuterium, a halogen atom, a cyano group, a C₁-C₁₀ alkyl group, a C₆-C₁₀ aryl group, or a combination thereof.

In particular, in Formulae 1 to 3, R₁₁ to R₁₃, R₂₁, R₃₁, X₂₂ and X₃₂ may each independently be H, D, F, Cl, CH₃, C₂H₅, C₃H₇, C₄H₉, CH(CH₃)₂, C(CH₃)₃, CH₂C(CH₃)₃, CH₂F, CHF₂, CF₃, CHFCH₃, CHFCH₂F, CHFCHF₂, CHFCF₃, CH₂CF₃, CF₂CH₃, CF₂CH₂F, CF₂CHF₂, CF₂CF₃, CH₂Cl, CHCl₂, CCl₃, CHClCH₃, CHClCH₂Cl, CHClCHCl₂, CHClCCl₃, CH₂CCl₃, CCl₂CH₃, CCl₂CH₂Cl, CCl₂CHCl₂, CCl₂CCl₃, CH₆, C₆F₆, CCl₆, CH₂C₆H₆, CH₂C₆F₆ or CH₂C₆Cl₆.

In an embodiment, the first repeating unit may be selected from the following Group I:

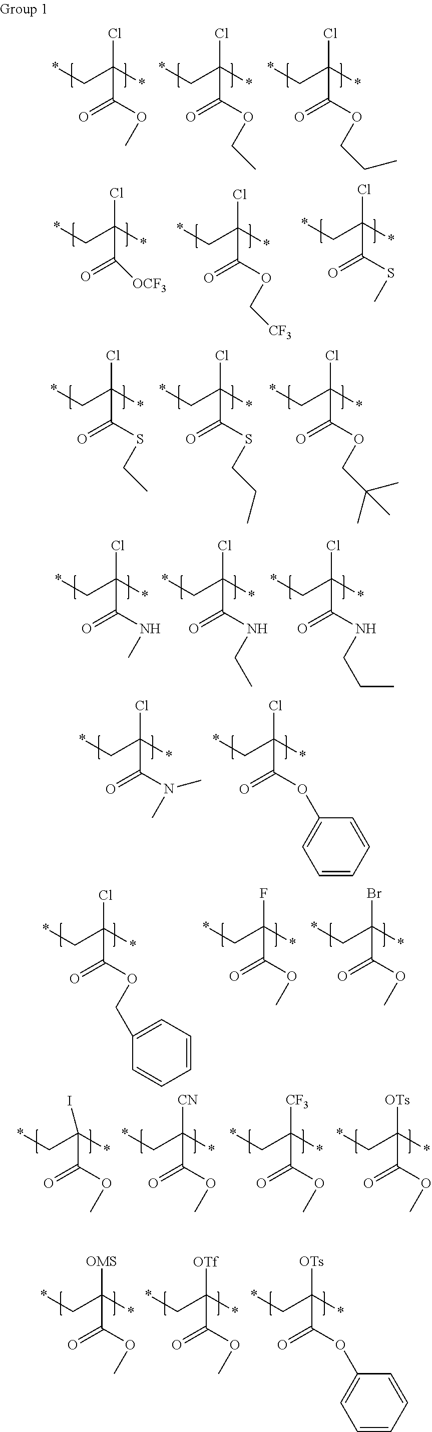

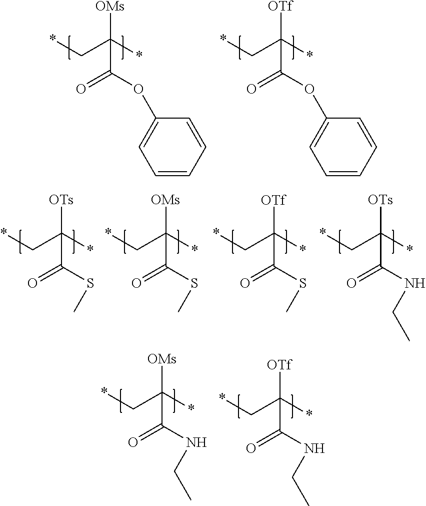

wherein in Group I,
OMs may be OSO₂CH₃, OTf may be OSO₂CF₃, OTs may be OSO₂C₆H₅(CH₃), and
* may be a bonding site with a neighboring atom.

In an embodiment, the second repeating unit may be selected from the following Group II:

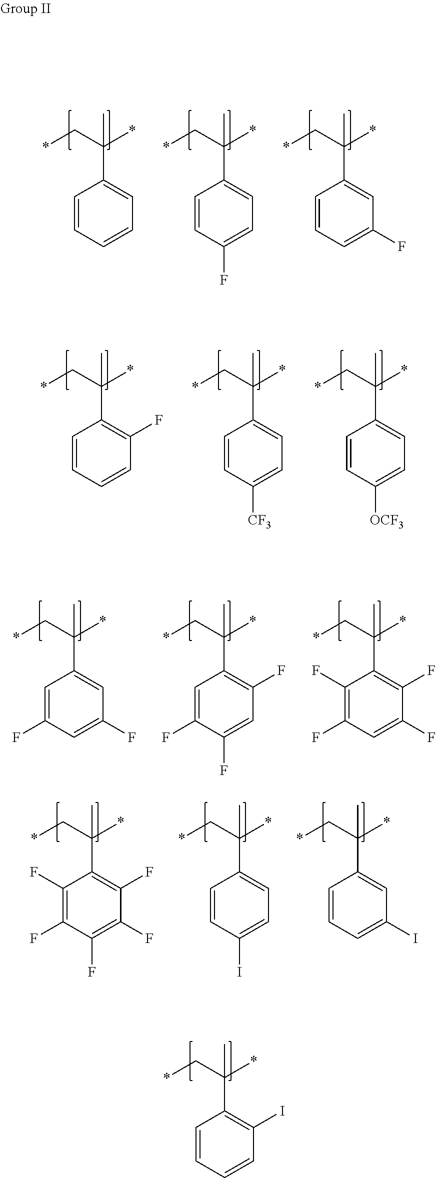

wherein in Group II, * indicates a bonding site with a neighboring atom.

In an embodiment, the third repeating unit may be selected from the following Group III:

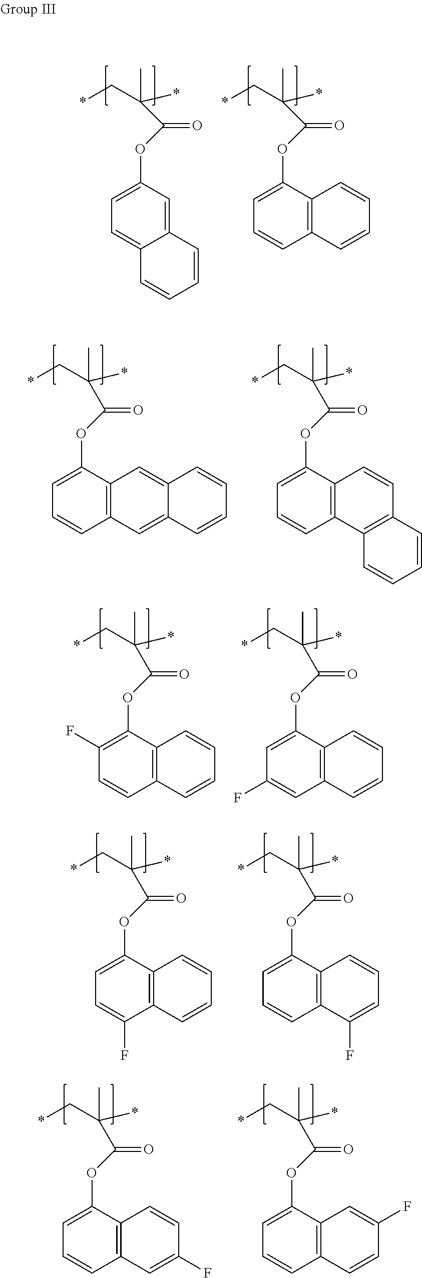

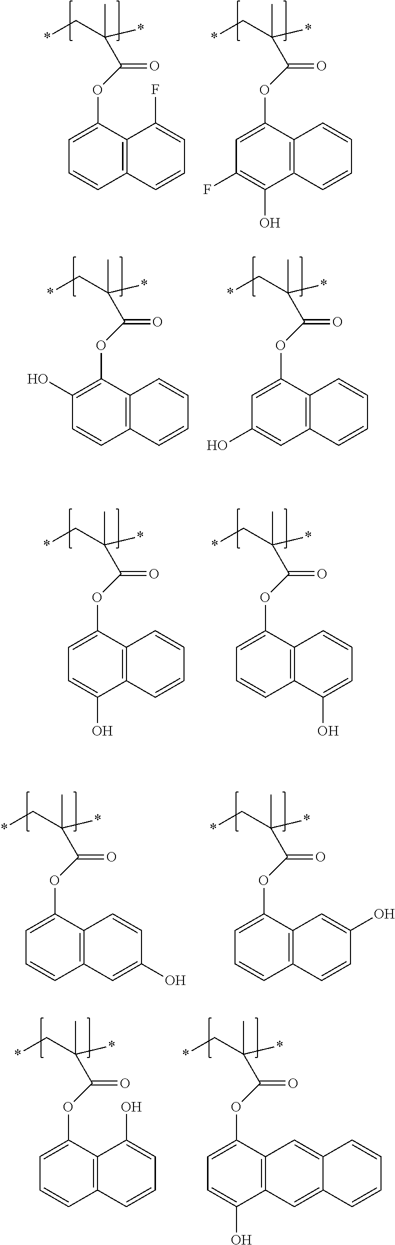

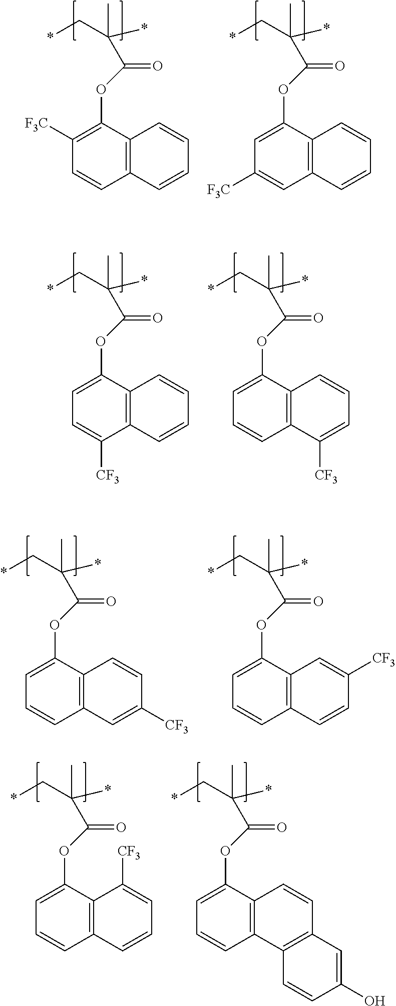

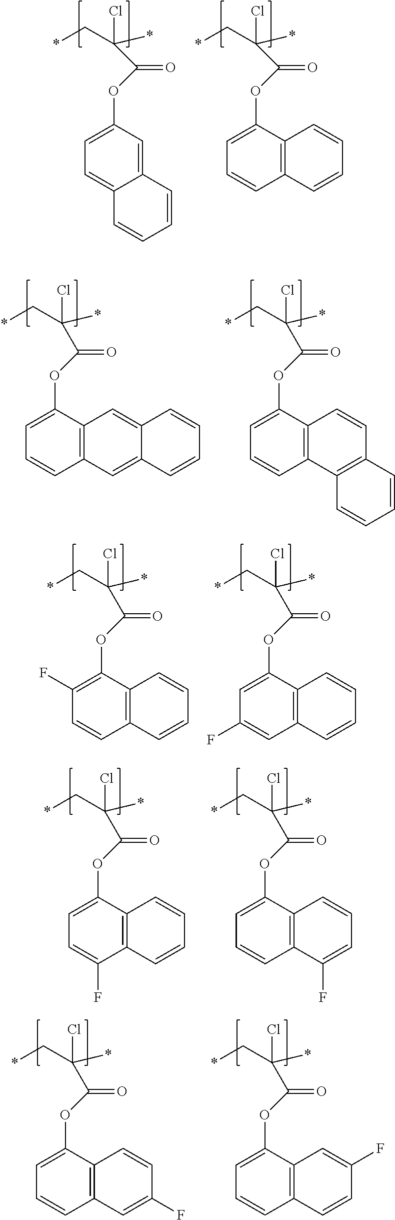

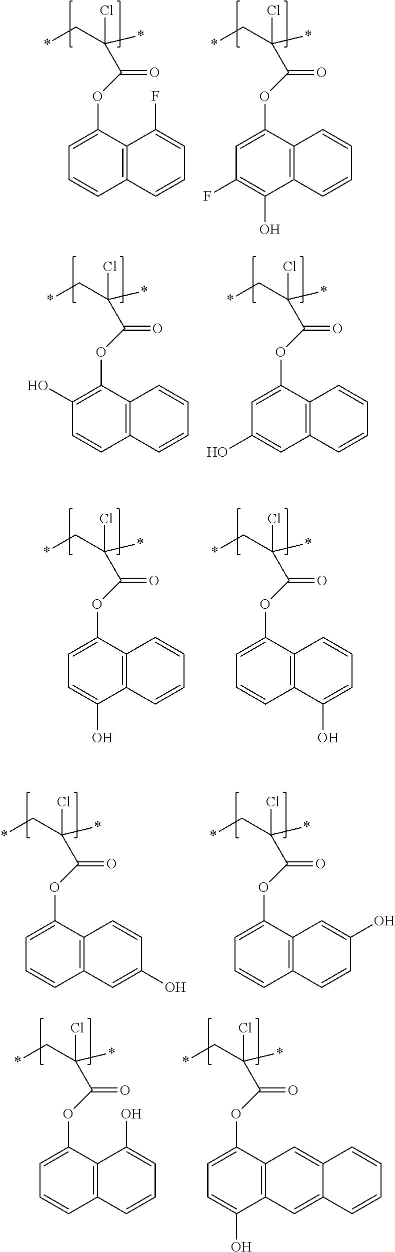

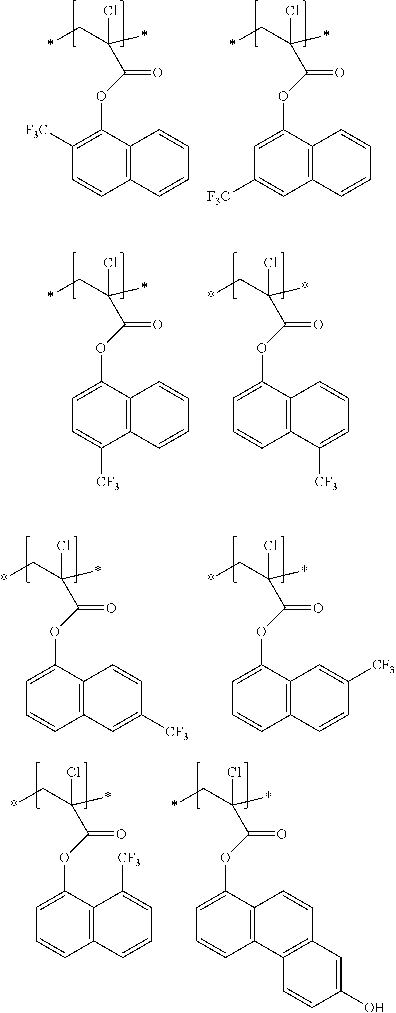

wherein in Group III, * indicates a bonding site with a neighboring atom.

In an embodiment, the polymer may consist of the first repeating unit, the second repeating unit, and the third repeating unit.

For example, the polymer may include about 1 mol % to about 98 mol %, specifically, about 5 mol % to about 90 mol %, more specifically, about 20 mol % to about 80 mol %, especially, about 30 mol % to about 70 mol %, of the first repeating unit; about 1 mol % to about 98 mol %, specifically, about 5 mol % to about 90 mol %, more specifically, about 20 mol % to about 80 mol %, especially, about 30 mol % to about 70 mol %, of the second repeating unit; and about 1 mol % to about 98 mol %, specifically, about 5 mol % to about 90 mol %, more specifically, about 20 mol % to about 80 mol %, especially, about 30 mol % to about 70 mol %, of the third repeating unit.

In particular, the polymer may include the first repeating unit to the second repeating unit in a molar ratio of about 5:1 to about 1:5, specifically, a molar ratio of about 3:1 to about 1:3, and more specifically, a molar ratio of about 2:1 to about 1:2.

In particular, the polymer may include the first repeating unit to the third repeating unit in a molar ratio of about 10:1 to about 1:3, specifically, a molar ratio of about 5:1 to about 1:2.

The polymer may have a weight average molecular weight (Mw) of about 1,000 to about 500,000, specifically, about 3,000 to about 100,000, more specifically, about 5,000 to about 50,000, as measured by gel permeation chromatography using tetrahydrofuran solvent and polystyrene as a standard material.

The polydispersity index (PDI: Mw/Mn) of the polymer may be from about 1.0 to about 4.0, specifically, from about 1.0 to about 3.5, and more specifically, from about 1.0 to about 2.0. When the above-described range is satisfied, the possibility of foreign matter remaining on the pattern may be reduced, or the deterioration of the pattern profile may be reduced and/or minimized. Accordingly, the resist composition may be more suitable for forming a fine pattern.

The polymer may have its properties changed by high-energy rays. Specifically, as the main chain of the polymer is decomposed, the molecular weight of the polymer decreases, and thus the solubility in a developer may increase. Since the polymer does not undergo property changes due to acid, degradation of the pattern caused by acid diffusion does not occur, making it advantageous for fine patterning.

Since the polymer includes a structure such as X₁₂, the stability of reactive intermediates generated during the polymer decomposition process is improved, thereby promoting the production of final decomposition products and limiting and/or minimizing side reactions.

Additionally, because the polymer includes a structure such as X₂₁, the resonance effect enhances the stability of the reactive intermediates generated during the polymer decomposition process. Furthermore, the steric effects of X₂₁ contribute to limiting and/or minimizing side reactions.

Since the polymer includes a third repeating unit, the solubility of the polymer may be improved, and accordingly, the contrast characteristics of a resist composition including the polymer may be improved, and a pattern formed using the polymer may have improved characteristics, such as an improved critical dimension (CD) value.

The polymer may be prepared by any suitable method, or a commercially available product may be used. For example, the polymer may be prepared by radical polymerization.

The structure (composition) of the polymer may be confirmed by performing FT-IR analysis, NMR analysis, X-ray fluorescence (XRF) analysis, mass spectrometry, UV analysis, single crystal X-ray structural analysis, powder X-ray diffraction (PXRD) analysis, liquid chromatography (LC) analysis, size exclusion chromatography (SEC) analysis, thermal analysis, etc. The detailed verification method is as described in the examples.

### [Resist Composition]

According to another aspect of the disclosure, a resist composition includes the above-described polymer and a solvent. The resist composition may have properties such as improved developability and/or improved resolution.

The solubility of the resist composition in a developer changes upon exposure to high-energy rays. The resist composition may be a positive resist composition in which an exposed portion of a resist film is dissolved and removed to form a positive resist pattern, or may be a negative resist composition in which an unexposed portion of a resist film is dissolved and removed to form a negative resist pattern. Specifically, the resist composition may be a positive resist composition.

In addition, the resist composition according to an embodiment may be for a dry developing process that does not use a solvent in the developing process when forming a resist pattern, or for an alkaline developing process that uses an alkaline developer, or for a solvent developing process that uses a developer containing an organic solvent (hereinafter, also referred to as an organic developer) in the developing process. In particular, the resist composition according to an embodiment may be for an alkaline developing process.

The resist composition may be substantially free of a compound having a molecular weight of 1,000 or more other than the polymer, since the properties of the polymer change upon exposure.

Additionally, the resist composition may substantially not include a photoacid generator.

The resist composition may not include an organometallic compound.

The polymer may be used in an amount of about 0.1 parts to about 80 parts by weight based on 100 parts by weight of the resist composition. Specifically, the polymer may be used in an amount of about 0.5 parts to about 5 parts by weight based on 100 parts by weight of the resist composition. If the above-described range is satisfied, any performance loss, such as reduced sensitivity and/or formation of foreign particles due to lack of solubility, may be reduced.

In addition, the polymer used in the resist composition may be used alone, or two or more different types may be used in combination.

As the polymer is as described above, the following describes the solvent and optional components such as a photoacid generator and quencher contained as needed.

### <Solvent>

The solvent included in the resist composition is not particularly limited as long as it can dissolve or disperse the polymer and any optional components included as needed.

The solvent may be used alone, or two or more different solvents may be used in combination.

The solvent may be an organic solvent or a mixed solvent of water and an organic solvent.

Examples of organic solvents may include alcohol-based solvents, ether-based solvents, ketone-based solvents, amide-based solvents, ester-based solvents, sulfoxide-based solvents, and hydrocarbon-based solvents.

More specifically, examples of the alcohol-based solvents may include: a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxy butanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonylalcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; a polyalcohol-based solvent such as ethyleneglycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethyleneglycol, dipropyleneglycol, triethylene glycol, and tripropylene glycol; and a polyalcohol-containing ether-based solvent such as ethyleneglycol monomethylether, ethyleneglycol monoethylether, ethyleneglycol monopropylether, ethyleneglycol monobutylether, ethyleneglycol monohexylether, ethyleneglycol monophenylether, ethyleneglycol mono-2-ethylbutylether, diethyleneglycol monomethylether, diethyleneglycol monoethylether, diethyleneglycol monopropylether, diethyleneglycol monobutylether, diethyleneglycol monohexyl ether, diethylene glycol dimethylether, propylene glycol monomethylether, propylene glycol dimethylether, propylene glycol monoethylether, propylene glycol monopropylether, propylene glycol monobutylether, dipropyleneglycol monomethylether, dipropyleneglycol monoethylether, and dipropyleneglycol monopropylether.

Examples of the ether-based solvents may include: a dialkylether-based solvent such as diethylether, dipropylether, and dibutylether; a cyclic ether-based solvent such as tetrahydrofuran and tetrahydropyran; and an aromatic ring-containing ether-based solvent such as diphenylether and anisole.

Examples of the ketone-based solvents may include: a chain-shaped ketone-based solvent such as acetone, methylethylketone, methyl-n-propylketone, methyl-n-butylketone, methyl-n-pentylketone, diethylketone, methylisobutylketone, 2-heptanone, ethyl-n-butylketone, methyl-n-hexylketone, diisobutylketone, trimethylnonanone, and 2,6-dimethylheptan-4-one; a cyclic ketone-based solvent such as cyclopentanone, cyclohexanone, cycloheptanone, cyclooctanone, and methylcyclohexanone; and 2,4-pentanedione, acetonylacetone, and acetphenone.

Examples of the amide-based solvents may include: a cyclic amide-based solvent such as N,N′-dimethylimidazolidinone and N-methyl-2-pyrrolidone; and a chain-shaped amide-based solvent such as N-methylformamide, N,N-dimethylformamide, N,N-diethylformamide, acetamide, N-methylacetamide, N,N-dimethylacetamide, and N-methylpropyoneamide.

Examples of the ester-based solvents may include: an acetate ester-based solvent such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, n-hexyl acetate, n-heptyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyalcohol-containing ethercarboxylate-based solvent such as ethyleneglycol monomethylether acetate, ethyleneglycol monoethylether acetate, diethyleneglycol monomethylether acetate, diethyleneglycol monoethylether acetate, diethyleneglycol mono-n-butyl ether acetate, propylene glycol monomethylether acetate (PGMEA), propylene glycol monoethylether acetate, propylene glycol monopropylether acetate, propylene glycol monobutylether acetate, dipropylene glycol monomethylether acetate, and dipropylene glycol monoethylether acetate; a lactone-based solvent such as γ-butyrolactone and 5-valerolactone; a carbonate-based solvent such as dimethyl carbonate, diethyl carbonate, ethylene carbonate, and propylene carbonate; a lactate ester-based solvent such as methyl lactate, ethyl lactate, n-butyl lactate, and n-amyl lactate; and glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-base solvents may include dimethyl sulfoxide and diethyl sulfoxide.

Examples of the hydrocarbon-based solvent may include aliphatic hydrocarbon solvents such as n-pentane, isopentane, n-hexane, isohexane, n-heptane, isoheptane, 2,2,4-trimethyl pentane, n-octane, isooctane, cyclohexane, and methylcyclohexane; and aromatic hydrocarbon solvents such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

Specifically, the organic solvent may be selected from alcohol-based solvents, amide-based solvents, ester-based solvents, sulfoxide-based solvents, and a combination thereof. More specifically, the solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide and a combination thereof.

Meanwhile, if an acid-labile group in acetal form is used, a high-boiling alcohol, such as diethylene glycol, propylene glycol, glycerol, 1,4-butanediol, or 1,3-butanediol, may be additionally added to accelerate the deprotection reaction of the acetal.

The solvent may be used in an amount of about 200 parts to about 20,000 parts by weight, specifically, about 2,000 parts to about 10,000 parts by weight, based on 100 parts by weight of the polymer.

### <Optional Component>

The resist composition may further include an acid generator, a quencher, a dissolution enhancer, a dissolution inhibitor, a surfactant, a crosslinking agent, a leveling agent, a colorant, or a combination thereof, as needed.

The resist composition may further include a surfactant to improve coatability, developability, and the like. Examples of the surfactant may include a nonionic surfactant such as polyoxyethylene lauryl ether, polyoxyethylene stearyl ether, polyoxyethyleneoleyl ether, polyoxyethylene n-octylphenyl ether, polyoxyethylene n-nonylphenyl ether, polyethyleneglycol dilaurate, and polyethyleneglycol distearate. Any commercially available product or a synthetic product may be used as the surfactant. Examples of the commercially available product may include KP341 (manufactured by Shin-Etsu Chemical Co., Ltd.), Polyflow No. 75 and Polyflow No. 95 (manufactured by Kyoeisha Chemical Co., Ltd.), Eftop EF301, Eftop EF303, and Eftop EF352 (manufactured by Mitsubishi Materials Electronic Chemicals Co., Ltd.), MEGAFACE© F171, MEGAFACE F173, R40, R41, and R43 (manufactured by DIC Corporation), Fluorad© FC430, Fluorad FC431 (manufactured by 3M Co., Ltd.), AsahiGuard AG710 (manufactured by AGC Co., Ltd.), and Surflon© S-382, Surflon SC-101, Surflon SC-102, Surflon SC-103, Surflon SC-104, Surflon SC-105, and Surflon SC-106 (manufactured by AGC Seimi Chemical Co., Ltd).

The surfactant may be included in an amount of about 0 part to about 20 parts by weight based on 100 parts by weight of the polymer.

The surfactant may be used alone, or two or more different types may be used in combination.

The method of producing the resist composition is not particularly limited, and for example, any method of mixing a polymer and optional components added as needed in a solvent may be used. Temperature or time in the mixing is not particularly limited. If necessary, filtration may be performed after the mixing.

### [Pattern Formation Method]

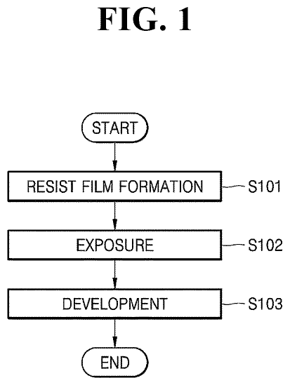

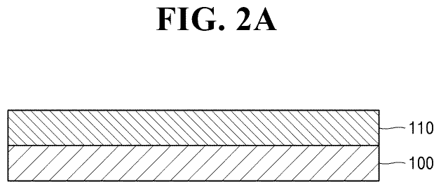

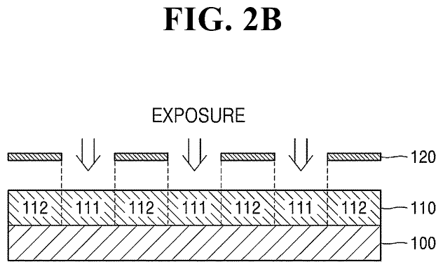

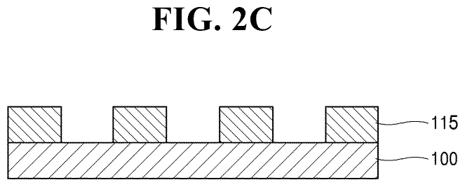

Hereinafter, a method of forming a pattern according to embodiments will be described in more detail with reference to FIG. 1 and FIGS. 2A to 2C. FIG. 1 is a flowchart illustrating a method of forming a pattern according to embodiments, and FIGS. 2A to 2C are cross-sectional side views illustrating a method of forming a pattern according to embodiments. Hereinafter, a method of forming a pattern by using a positive resist composition will be described by way of an example, but the embodiment is not limited thereto.

Referring to FIG. 1, a method of forming a pattern includes applying a resist composition to form a resist film (S101), exposing at least a portion of the resist film to high-energy rays (S102) to provide an exposed resist film, and developing the exposed resist film using a developer (S103). These operations may be omitted or may be performed in a different order, if necessary.

First, a substrate 100 is prepared. The substrate 100 may be a semiconductor substrate such as a silicon substrate and a germanium substrate, or may be formed of glass, quartz, ceramic, copper, or the like. In some embodiments, the substrate 100 may include Groups Ill to V compounds, such as GaP, GaAs, and GaSb.

A resist film 110 may be formed on the substrate 100 by applying the resist composition thereto to a desired thickness using a coating method. If necessary, a post application bake (PAB) may be performed to remove the organic solvent remaining in the resist film 110.

As the coating method, spin coating, dipping, roller coating, or other common coating methods may be used. Among them, spin coating may be used in particular, and the resist film 110 having a desired thickness may be formed by adjusting viscosity, concentration, and/or spin speed of the resist composition. Specifically, the resist film 110 may have a thickness of about 10 nm to about 300 nm. More specifically, the resist film 110 may have a thickness of about 30 nm to about 200 nm.

The lower limit of a PAB temperature may be 60° C. or higher, specifically, 80° C. or higher. In addition, the upper limit of the PAB temperature may be 150° C. or less, specifically, 140° C. or lower. The lower limit of a PAB time may be 5 seconds or more, specifically, 10 seconds or more. The upper limit of the PAB time may be 600 seconds or less, specifically, 300 seconds or less.

Before applying the resist composition on the substrate 100, a film to be etched (not shown) may be also formed on the substrate 100. The film to be etched may refer to a layer onto which an image is transferred from a resist pattern and converted into a pattern. In an embodiment, the film to be etched may be formed to include, for example, an insulating material such as a silicon oxide, a silicon nitride, and a silicon oxynitride. In some embodiments, the film to be etched may be formed to include a conductive material such as a metal, a metal nitride, a metal silicide, and a metal silicide nitride film. In some embodiments, the film to be etched may be formed to include a semiconductor material such as polysilicon.

In an embodiment, an anti-reflection film may further be formed on the substrate 100 to improve and/or maximize efficiency of the resist. The anti-reflection film may be an organic or inorganic anti-reflection film.

In an embodiment, a protective film may further be formed on the resist film 110 to reduce effects of alkaline impurities included during a process. In addition, in the case of performing immersion lithography, a protective film for immersion lithography may be formed on the resist film 110 to avoid direct contact between an immersion medium and the resist film 110.

Subsequently, at least a portion of the resist film 110 may be exposed to high-energy rays. For example, high-energy rays having passed through a mask 120 may reach at least one portion of the resist film 110. Therefore, the resist film 110 may have an exposed portion 111 and an unexposed portion 112.

Although not limited to a specific theory, radicals are generated in the exposed portion 111 by exposure, and this may cause the main chain of the polymer to decompose, thereby changing the properties of the resist composition.

In some cases, the exposure may be performed by irradiating high-energy rays through a mask with a certain pattern by using a liquid such as water as a medium. Examples of the high-energy rays may include electromagnetic waves such as ultraviolet rays, deep ultraviolet (DUV) rays, extreme ultraviolet (EUV) rays (wavelength of 13.5 nm), X-rays, and γ-rays; and charged particle beams such as electron beams (EBs) and α particle beams. Irradiation of these high-energy rays may be collectively referred to as “exposure.”

Various light sources may be used for the exposure, for example, a light source emitting laser beams in the UV range, such as a KrF excimer laser (wavelength of 248 nm), an ArF excimer laser (wavelength of 193 nm), and an F2 excimer laser (wavelength of 157 nm), a light source emitting harmonic laser beams in the far ultraviolet or vacuum ultraviolet range by converting wavelengths of laser beams received from a solid laser light source (YAG or semiconductor laser), and a light source emitting EBs or EUVs may be used. During exposure, the exposure may be usually performed through a mask corresponding to a desired pattern, but when exposure light is an EB, the exposure may be performed through direct writing without using a mask.

The integrated dose of high-energy rays, for example, when using extreme ultraviolet rays as high-energy rays, may be 2000 mJ/cm² or less, specifically 500 mJ/cm² or less. In addition, when EBs are used as the high energy rays, the integral dose may be 5,000 μC/cm² or less, or 1,000 μC/cm² or less.

Additionally, a post exposure bake (PEB) may be performed. The lower limit of the temperature of PEB may be 50° C. or more, specifically 80° C. or more. The upper limit of the PEB temperature may be 180° C. or lower, specifically 130° C. or lower. The lower limit of the time of the PEB time may be 5 seconds or more, specifically 10 seconds or more. The upper limit of the time of the PEB may be 600 seconds or less, specifically 300 seconds or less.

Next, the exposed resist film 110 may be developed using a developer to form a resist pattern 115.

Examples of the developer may include distilled water, an alkaline developer, and a developer including an organic solvent (hereinafter also referred to as “organic developer”). Examples of a development method may include a dipping method, a puddle method, a spray method, and a dynamic injection method. The developing temperature may be, for example, about 5° C. or more and about 60° C. or less, and a developing time may be, for example, about 5 seconds or more and about 300 seconds or less.

Examples of the alkaline developer may include an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

The lower limit of an amount of the alkaline compound included in the alkaline developer may be 0.1 wt % or more, specifically 0.5 wt % or more, and more specifically 1 wt % or more. Additionally, the upper limit of the amount of the alkaline compound included in the alkaline developer may be 20 wt % or less, specifically 10 wt % or less, and more specifically 5 wt % or less.

After development, the resist pattern may be washed with ultrapure water, and then any water remaining on the substrate and pattern may be removed.

Examples of the organic solvent included in the organic developer may include the same organic solvents as those exemplified in the part of <Solvent> of [Resist composition].

The lower limit of the organic solvent content in the organic developer may be 80 wt % or more, specifically 90 wt % or more, more specifically 95 wt % or more, and especially 99 wt % or more.

In an embodiment, the developer may include distilled water, an alkaline developer, or a combination thereof, and the exposed portion 111 may be removed by the developer.

The organic developer may also include surfactants. Additionally, the organic developer may include trace amounts of moisture. Additionally, development may be stopped by substituting a different type of solvent from the organic developer during development.

The resist pattern after development may be further cleaned. Cleaning solutions such as ultrapure water and rinse solution may be used. There are no particular restrictions on the rinse solution as long as it does not dissolve the resist pattern, and common solutions containing organic solvents may be used. For example, the rinse solution may be an alcohol-based solvent or an ester-based solvent. After cleaning, any remaining rinse solution on the substrate and the resist pattern may be removed. When ultrapure water is used, any remaining water on the substrate and pattern may be removed.

Additionally, the developer may be used alone or in combination of two or more types.

As described above, after forming the resist pattern, a patterned wiring substrate may be obtained by etching. The etching method may be carried out using well-known methods such as dry etching with plasma gas, and wet etching with alkaline solutions, copper (II) chloride solutions, or iron (Ill) chloride solutions.

After forming the resist pattern, plating may also be performed. The plating method is not particularly limited, but examples include copper plating, solder plating, nickel plating, and gold plating.

The remaining resist pattern after etching may be stripped using an organic solvent. Examples of such organic solvents may include, but are not limited to, propylene glycol monomethyl ether acetate (PGMEA), propylene glycol monomethyl ether (PGME), and ethyl lactate (EL). The stripping method is not particularly limited and may include, for example, immersion methods and spray methods. Additionally, the wiring substrate with the resist pattern formed may be a multilayer wiring substrate and may have small-diameter through holes.

In an embodiment, the wiring substrate is formed by depositing metal in a vacuum after forming the resist pattern, and then dissolving the resist pattern in a solution, a method known as the lift-off method.

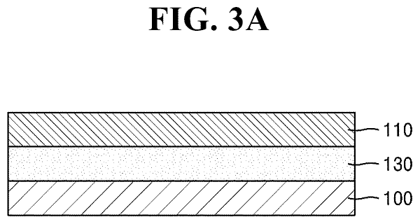

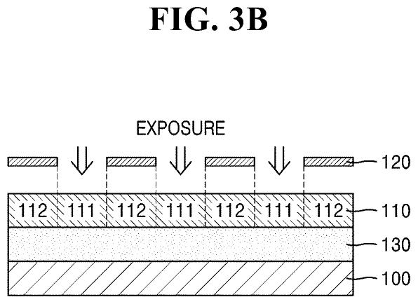

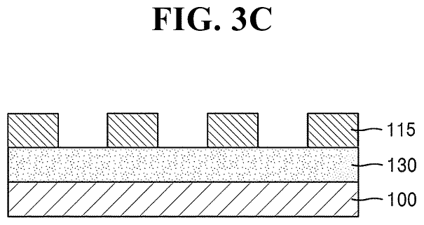

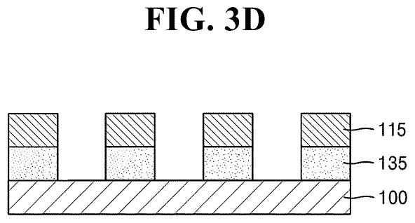

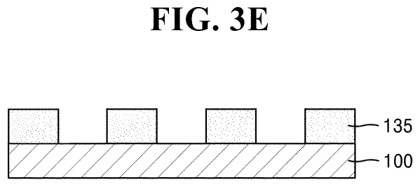

FIGS. 3A to 3E are cross-sectional side views showing a method of forming a patterning structure according to an embodiment.

As shown in FIG. 3A, a material layer 130 may be formed on the substrate 100 before forming the resist film 110 on the substrate 100. The resist film 110 may be formed on top of the material layer 130. The material layer 130 may include an insulating material (e.g., silicon oxide, silicon nitride), a semiconductor material (e.g., silicon), or a metal (e.g., copper). In some embodiments, the material layer 130 may have a multi-layer structure.

The material of the material layer 130 may be different from the material of the substrate 100.

As shown in FIG. 3B, the resist film 110 may undergo a prebake process before exposure and then be exposed to high-energy rays through the mask 120, and subsequently the resist film 110 may include an exposed portion 111 and an unexposed portion 112.

As shown in FIG. 3C, the exposed resist film 110 may be developed using a developer. The exposed portion 111 may be washed away by the developer, while the unexposed portion 112 remain without being washed away by the developer.

As shown in FIG. 3D, the resist pattern 115 may serve as a mask for etching the exposed portions of the material layer 130 to form the material pattern 135 on the substrate 100.

As shown in FIG. 3E, the resist pattern 115 may be removed.

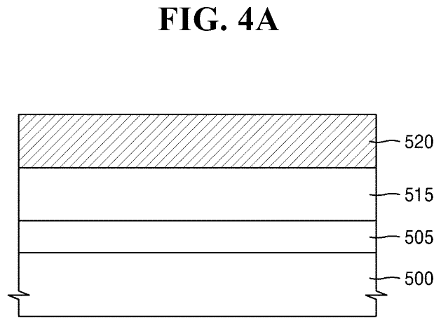

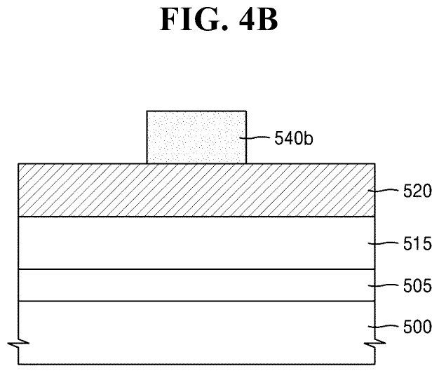

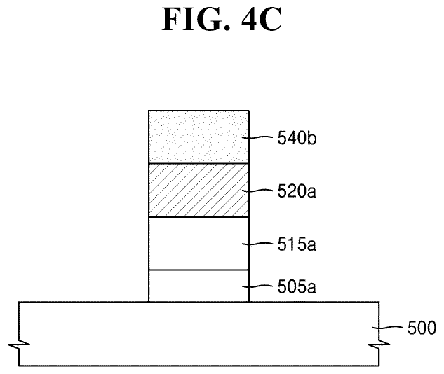

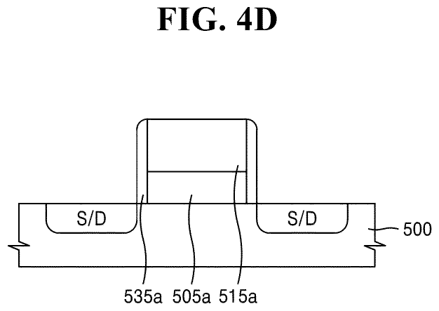

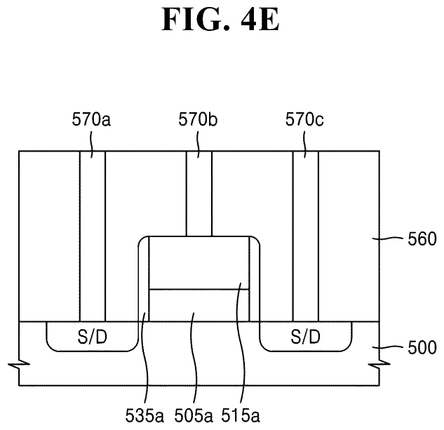

FIGS. 4A to 4E are cross-sectional side views showing a method of forming a semiconductor device according to an embodiment.

As shown in FIG. 4A, a gate dielectric 505 (e. g., silicon oxide) may be formed on the substrate 500. The substrate 500 may be a semiconductor substrate such as a silicon substrate. A gate layer 515 (e.g., doped polysilicon) may be formed on gate dielectric 505.

A hardmask layer 520 may be formed on the gate layer 515.

As shown in FIG. 4B, a resist pattern 540b may be formed on the hardmask layer 520. The resist pattern 540b may be formed using a resist composition according to an embodiment. The resist composition may include an organic solvent.

As shown in FIG. 4C, the gate layer 515 and the gate dielectric 505 may be etched to form a hard mask pattern 520a, a gate electrode pattern 515a, and a gate dielectric pattern 505a.

As shown in FIG. 4D, a spacer layer may be formed on the gate electrode pattern 515a and the gate dielectric pattern 505a. The spacer layer may be formed using a deposition process (e.g., CVD). The spacer layer may be etched to form spacers 535a (e.g., silicon nitride) on the sidewalls of the gate electrode pattern 515a and the gate dielectric pattern 505a. After forming the spacers 535a, ions may be implanted into the substrate 500 to form source/drain impurity regions (S/D).

As shown in FIG. 4E, an interlayer insulating film 560 (e.g., an oxide) may be formed on the substrate 500, covering the gate electrode pattern 515a, gate dielectric pattern 505a, and spacers 535a. Subsequently, the interlayer insulating film 560 may have electrical contacts 570a, 570b, and 570c formed to connect with the gate electrode pattern 515a and the S/D regions. The electrical contacts 570a, 570b, and 570c may be formed of a conductive material (e.g., metal). Although not shown, a barrier layer may be formed between the sidewalls of the interlayer insulating film 560 and the electrical contacts 570a, 570b, and 570c.

FIGS. 4A to 4E show examples of forming transistors, but the disclosure is not limited thereto.

The resist composition according to an embodiment may be used in the patterning process to form other types of semiconductor devices.

For example, although not illustrated in FIGS. 4D and 4E, in some embodiments, the hard mask pattern 520a may not be removed before the spacer 535a is formed. For example, if the hard mask pattern 520a is not removed, then the hard mask pattern 520a may remain on top of the gate electrode pattern 515a in FIGS. 4D and 4E, the spacer 535a may cover a sidewall of the hard mask pattern 520a in FIGS. 4D and 4E, and the electrical contact 570b may extend through an opening in the hard mask pattern 520a to directly contact an upper surface of the gate electrode 515a.

While the disclosure will be described in more detail using the following examples and comparative examples, the technical scope of the disclosure is not limited to these examples.

### EXAMPLES

### Synthesis Example 1: Synthesis of Polymer P-1

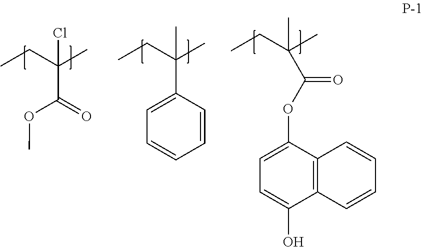

Using the input ratio shown in Table 1, Monomer M-1 (methyl 2-chloroacrylate), Monomer M-2 (α-methyl styrene), Monomer M-3 (4-hydroxynaphthalen-1-yl methacrylate), and V601 (dimethyl 2,2′-azobis(2-methylpropionate) were dissolved in 5 mL of dioxane and reacted at 70° C. for 8 hours. The reaction solution was treated with MeOH for precipitation, and the resulting solid was dried at 40° C. for 24 hours to obtain Polymer P-1 with a molar ratio of 35/56/9, Mn of 13,861, Mw of 23,286, and PDI of 1.68.

### Synthesis Examples 2 to 4: Synthesis of Polymers P-2, X-1 and X-2

Polymers P-2, X-1, and X-2 were synthesized using the same method as in Synthesis Example 1, except that, instead of monomers M-1, M-2 and M-3, the monomers in Table 1 were used at the input ratios in Table 1.

TABLE 1

| | | | ¹H-NMR | Number | Weight | |
|---|---|---|---|---|---|---|
| | | Input | analysis | average | average | |
| | | ratio | ratio | molecular | molecular | |
| | | (molar | (molar | weight | weight | |
| Polymer | Monomer | ratio) | ratio) | (Mn) | (Mw) | PDI |
| P-1 | M-1: | 36:54:10 | 35:56:9 | 13,861 | 23,286 | 1.68 |
| | M-2:M-3 | | | | | |
| P-2 | M-1: | 45:45:10 | 49:47:4 | 25,076 | 47,644 | 1.9 |
| | M-2:M-4 | | | | | |
| X-1 | M-1: | 45:45:10 | 43.5:43.5:13 | 12,370 | 21,029 | 1.7 |
| | M-2:M-5 | | | | | |
| X-2 | M-1:M-2 | 55:45 | 57:43 | 10,700 | 14,980 | 1.4 |

M-1 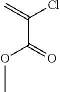
M-2 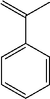
M-3 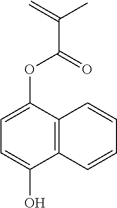 [SMILES: C=C(C)C(=O)Oc1ccc(O)c2ccccc12]
M-4 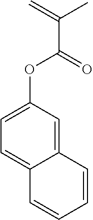 [SMILES: C=C(C)C(=O)Oc1ccc2ccccc2c1]
M-5 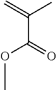
P-1 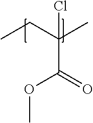 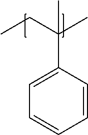 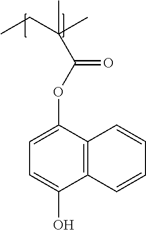
P-2 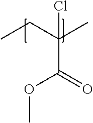 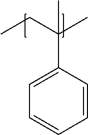 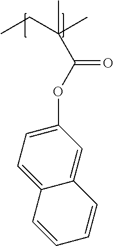
X-1 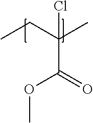 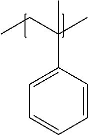 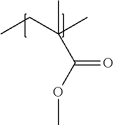
X-2

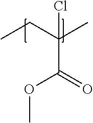

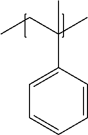

### Evaluation Example 1: Thin Film Phenomena Evaluation

### (1) Terminology

In this evaluation, the thickness of the resist film was measured before and after development. The ratio (e.g., normalized remaining thickness (NRT) ratio) was plotted against the dose to obtain a contrast curve, from which E₀, E₁, and γ were derived.

NRT=(thickness after development)/(thickness before development)

Here, E₀ refers to the exposure amount at the point where the resist film is completely developed (the resist film thickness no longer decreases), and E₁ refers to the exposure amount at the point where the resist film begins to develop. γ is the sensitivity, calculated using the following Equation 1:

$$γ = {[ log ( \frac{{E}_{0}}{{E}_{1}} ) ]}^{- 1} \qquad Equation 1$$

Additionally, dark loss indicates the relative thickness of the unexposed resist film after development.

### (2) E-beam Thin Film Phenomenon Evaluation

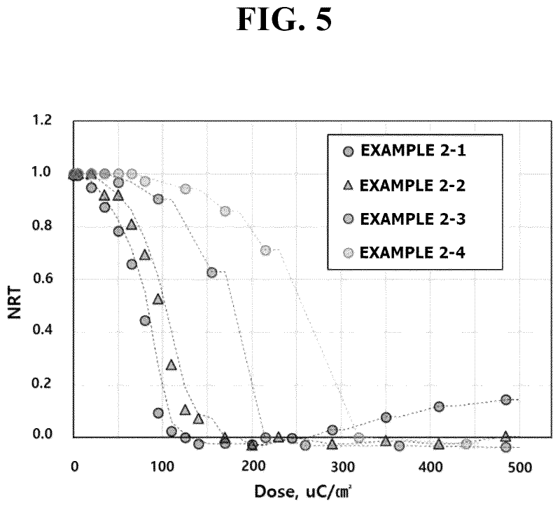

Polymer P-2 was dissolved in a propylene glycol methyl ether acetate (PGMEA) solvent at a concentration of 2 wt % to prepare a resist solution. The solution was applied onto an HMDS-treated 8-inch silicon wafer by spin coating at 1500 rpm and heated at 120° C. for 60 seconds to form a 40 nm thick resist film. Next, E-beam exposure was performed using a JEOL JBX-8100FS system. The exposure area was 30×30 μm², and exposure was carried out at 35 points within a dose range of 10 μC/cm² to 700 μC/cm². No additional post-exposure bake (PEB) was performed. Subsequently, development was performed for 30 seconds using the following developers: n-pentyl acetate, n-hexyl acetate, n-heptyl acetate, or 2,6-dimethylheptan-4-one. The results are shown in FIG. 5 and Table 2 below.

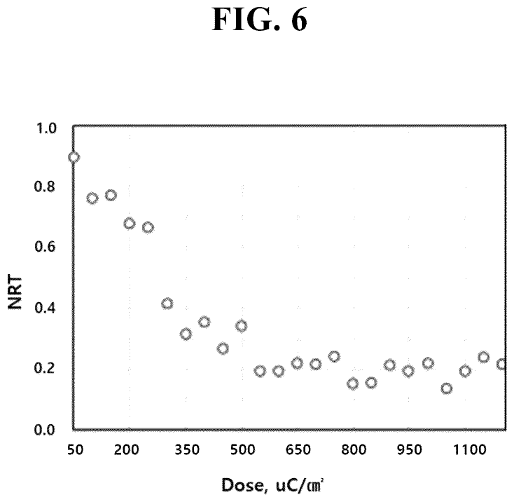

Similarly, Polymers P-1, X-1, and X-2 were developed using the developers listed in Table 3, following the same procedure as Polymer P-2, with the results shown in Table 2. The results using n-heptyl acetate developer for Polymer X-2 are shown in FIG. 6.

TABLE 2

| | | | | E₁ | E₀ | |
|---|---|---|---|---|---|---|
| | | | Dark- | (mJ/ | (mJ/ | |
| | Polymer | Developer | Loss | cm²) | cm²) | γ |
| Example 1-1 | P-1 | n-pentyl acetate | 32 | 5 | 100 | 1 |
| Example 1-2 | P-1 | n-hexyl acetate | 7 | 20 | 100 | 1.4 |
| Example 1-3 | P-1 | n-heptyl acetate | 4.6 | 50 | 160 | 2 |
| Example 2-1 | P-2 | n-pentyl acetate | 9 | 50 | 170 | 2 |
| Example 2-2 | P-2 | n-hexyl acetate | 1 | 35 | 245 | 1.2 |
| Example 2-3 | P-2 | n-heptyl acetate | 1.5 | 95 | 245 | 2.4 |
| Example 2-4 | P-2 | 2,6-dimethylheptan- | 0.52 | 65 | 200 | 2.0 |
| | | 4-one | | | | |
| Comparative | X-1 | n-pentyl acetate | 7.4 | 15 | 130 | 1.2 |
| Example 1-1 | | | | | | |
| Comparative | X-1 | n-hexyl acetate | 1.3 | 20 | 135 | 1.2 |
| Example 1-2 | | | | | | |
| Comparative | X-1 | n-heptyl acetate | 0.2 | 35 | 185 | 1.4 |
| Example 1-3 | | | | | | |
| Comparative | X-2 | n-pentyl acetate | 38 | 50 | 500 | 0.9 |
| Example 2-1 | | | | | | |
| Comparative | X-2 | n-hexyl acetate | 12 | 73 | 310 | 1 |
| Example 2-2 | | | | | | |
| Comparative | X-2 | n-heptyl acetate | 10 | 110 | 650 | 1.1 |
| Example 2-3 | | | | | | |

Referring to Table 2, it was confirmed that under the same phenomenon conditions, both Polymers P-1 and P-2 have improved contrast characteristics (γ) and/or enhanced dark loss properties compared to Polymers X-1 and X-2.

### Evaluation Example 2 Pattern Development Evaluation

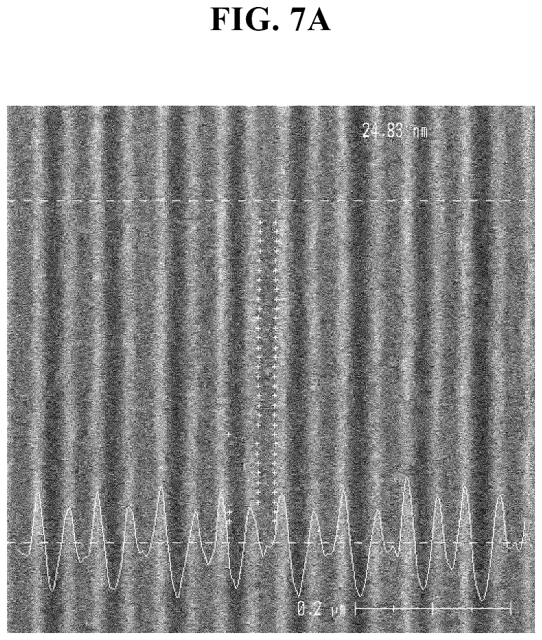

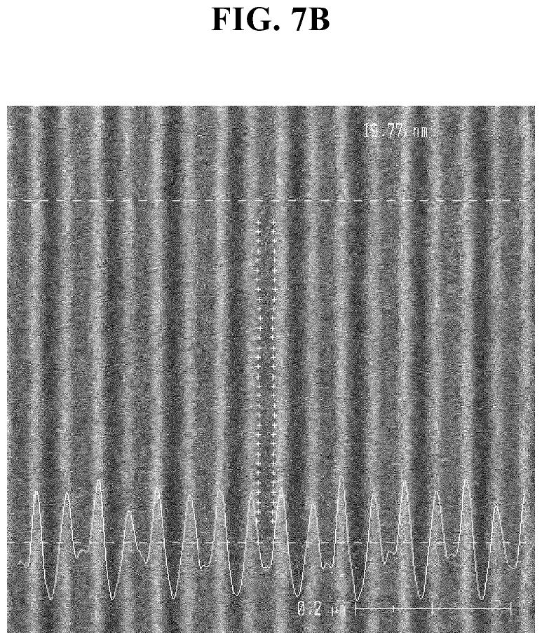

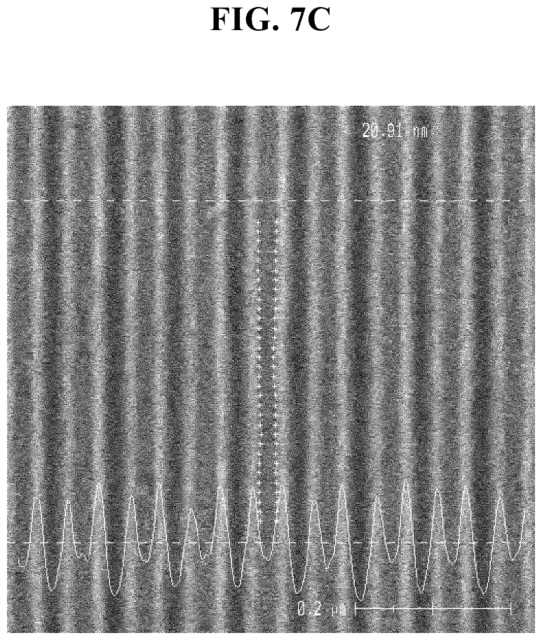

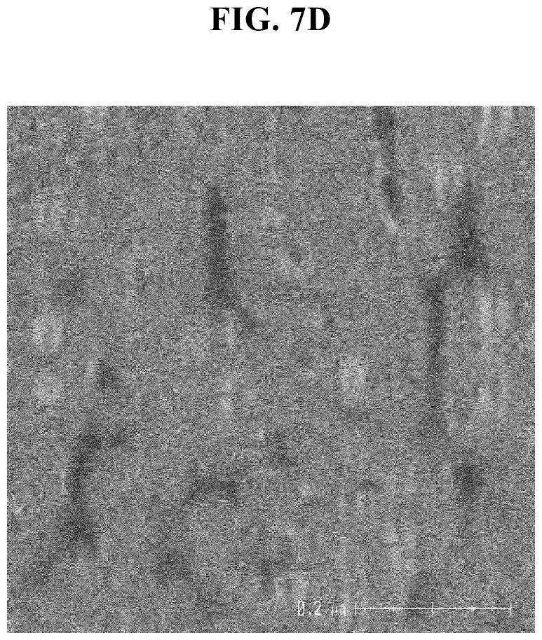

Polymer P-2 was dissolved in a PGMEA solvent at a concentration of 2 wt % to prepare a resist solution. The solution was applied onto an HMDS-treated 8-inch silicon wafer by spin coating at 1500 rpm and heated at 120° C. for 60 seconds to form a 40 nm thick resist film. Next, E-beam exposure was performed using a JEOL JBX-8100FS system. For line-and-space (LS) patterns, exposure was conducted at the doses listed in Table 3. No additional PEB was performed. The resist film was then developed using pentyl acetate for 30 seconds. The widths of multiple LS patterns and the gaps between them were measured using a Hitachi CG4000 system to calculate the critical dimension (CD). The results are presented in FIGS. 7A to 7C and Table 3.

For comparison, Polymer X-2 was used instead of Polymer P-2, and exposure was conducted at a dose of 550 μC/cm². Other steps, including CD calculation, were performed in the same manner as for Polymer P-2. The results are shown in FIG. 7D and Table 3.

TABLE 3

| | | Dose | | CD | |
|---|---|---|---|---|---|
| | Polymer | (μC/cm²) | Developer | (nm) | FIG. |
| Example 3-1 | P-2 | 385 | Pentyl acetate | 24.83 | 7A |
| Example 3-2 | P-2 | 370 | Pentyl acetate | 19.77 | 7B |
| Example 3-3 | P-2 | 355 | Pentyl acetate | 20.91 | 7C |
| Comparative | X-2 | 550 | Pentyl acetate | No pattern | 7D |
| Example 3-1 | | | | formed | |

Referring to Table 3, it can be seen that Polymer P-2 forms a uniform pattern compared to Polymer X-2.

Embodiments of the disclosure may provide a resist composition having improved sensitivity and/or resolution.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A polymer comprising:
a first repeating unit represented by Formula 1;
a second repeating unit represented by Formula 2; and
a third repeating unit represented by Formula 3, 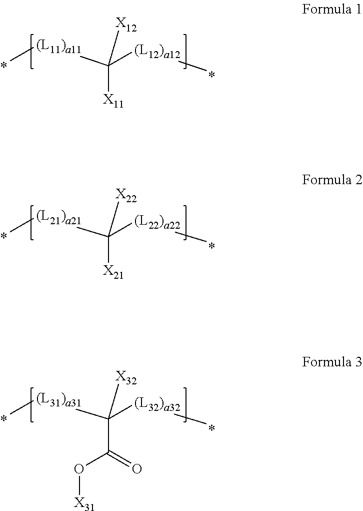
wherein in Formulae 1 to 3,
L₁₁ and L₁₂ are each independently a single bond, O, S, C(═O), C(═O)O, OC(═O), C(═O)NR₁₁, NR₁₁C(═O), S(═O), S(═O)₂, S(═O)₂O, OS(═O)₂, or a linear, branched or cyclic C₁-C₃₀ divalent hydrocarbon group optionally including a heteroatom,
L₂₁ and L₂₂ are each independently a single bond, O, S, C(═O), C(═O)O, OC(═O), C(═O)NR₂₁, NR₂₁C(═O), S(═O), S(═O)₂, S(═O)₂O, OS(═O)₂, or a linear, branched or cyclic C₁-C₃₀ divalent hydrocarbon group optionally including a heteroatom,
L₃₁ and L₃₂ are each independently a single bond, O, S, C(═O), C(═O)O, OC(═O), C(═O)NR₃₁, NR₃₁C(═O), S(═O), S(═O)₂, S(═O)₂O, OS(═O)₂, or a linear, branched or cyclic C₁-C₃₀ divalent hydrocarbon group optionally including a heteroatom,
a₁₁, a₁₂, a₂₁, a₂₂, a₃₁ and a₃₂ are each independently an integer from 1 to 4,
X₁₁ is CN, C(═O)R₁₂, C(═O)OR₁₂, C(═O)SR₁₂, or C(═O)NR₁₂R₁₃,
X₁₂ is an electron withdrawing group,
X₂₁ is a substituted or unsubstituted C₆-C₃₀ aryl group,
X₃₁ is a substituted or unsubstituted C₁₀-C₂₀ aryl group,
R₁₁ to R₁₃, R₂₁, R₃₁, X₂₂ and X₃₂ are each independently hydrogen, deuterium, a halogen atom, a cyano group, or a linear, branched or cyclic C₁-C₃₀ monovalent hydrocarbon group optionally including a heteroatom, and
* is a bonding site with a neighboring atom.

2. The polymer of claim 1,
wherein L₁₁, L₁₂, L₂₁, L₂₂, L₃₁ and L₃₂ are each independently a single bond, O, S, C(═O), C(═O)O, OC(═O), C(═O)NH, NHC(═O), S(═O), S(═O)₂, S(═O)₂O, OS(═O)₂, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

3. The polymer of claim 1,
wherein one of (L₁₁)ₐ₁₁ and (L₁₂)ₐ₁₂ is a single bond, and an other of (L₁₁)ₐ₁₁ and (L₁₂)ₐ₁₂ is selected from: O; C(═O); C(═O)O; OC(═O); and a C₁-C₁₀ alkylene group unsubstituted or substituted with deuterium, a halogen atom, a C₁-C₂₀ alkyl group, a C₁-C₂₀ halogenated alkyl group, a C₁-C₂₀ alkoxy group, or a combination thereof;
one of (L₂₁)ₐ₂₁ and (L₂₂)ₐ₂₂ is a single bond, and an other of (L₂₁)ₐ₂₁ and (L₂₂)ₐ₂₂ is selected from: O; C(═O); C(═O)O; OC(═O); and a C₁-C₁₀ alkylene group unsubstituted or substituted with deuterium, a halogen atom, a C₁-C₂₀ alkyl group, a C₁-C₂₀ halogenated alkyl group, a C₁-C₂₀ alkoxy group, or a combination thereof; and
one of (L₃₁)ₐ₃₁ and (L₃₂)ₐ₃₂ is a single bond, and an other of (L₃₁)ₐ₃₁ and (L₃₂)ₐ₃₂ is selected from: O; C(═O); C(═O)O; OC(═O); and a C₁-C₁₀ alkylene group unsubstituted or substituted with deuterium, a halogen atom, a C₁-C₂₀ alkyl group, a C₁-C₂₀ halogenated alkyl group, a C₁-C₂₀ alkoxy group, or a combination thereof.

4. The polymer of claim 1,
wherein X₁₁ is represented by any one of Formulae 4-1 to 4-4: 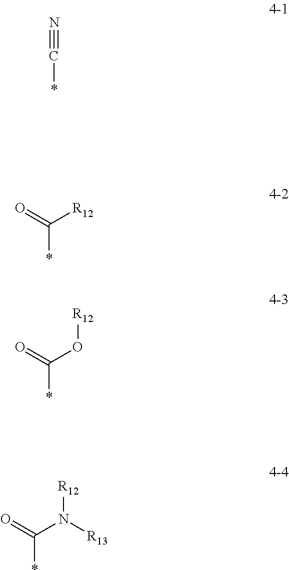
wherein in Formulae 4-1 to 4-4,
R₁₂ and R₁₃ are each the same as defined in Formula 1, and
* is a bonding site with a neighboring atom.

5. The polymer of claim 1,
wherein X₁₂ is selected from: a halogen atom; a cyano group; a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each substituted with a halogen atom, a cyano group, a C₁-C₂₀ halogenated alkyl group, or a combination thereof; and SO₃Rₓ, and
Rₓ is selected from a C₁-C₁₀ alkyl group and a C₆-C₁₀ aryl group, each unsubstituted or substituted with deuterium, a halogen atom, a cyano group, a C₁-C₂₀ alkyl group, a C₁-C₂₀ halogenated alkyl group, a C₁-C₂₀ alkoxy group, or a combination thereof.

6. The polymer of claim 1,
wherein X₂₁ is selected from a C₆-C₂₀ aryl group unsubstituted or substituted with deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylate anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or a combination thereof.

7. The polymer of claim 1,
wherein X₃₁ is represented by any one of Formulae 5-1 to 5-26: 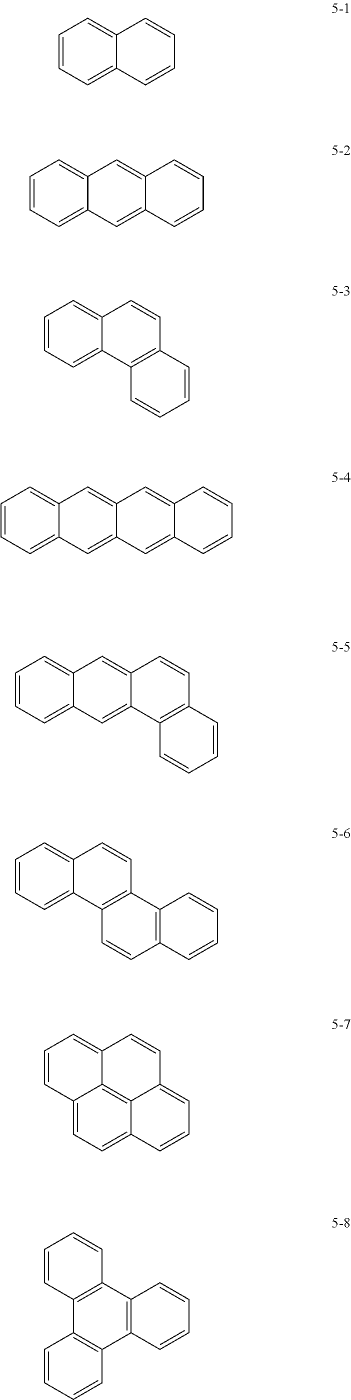 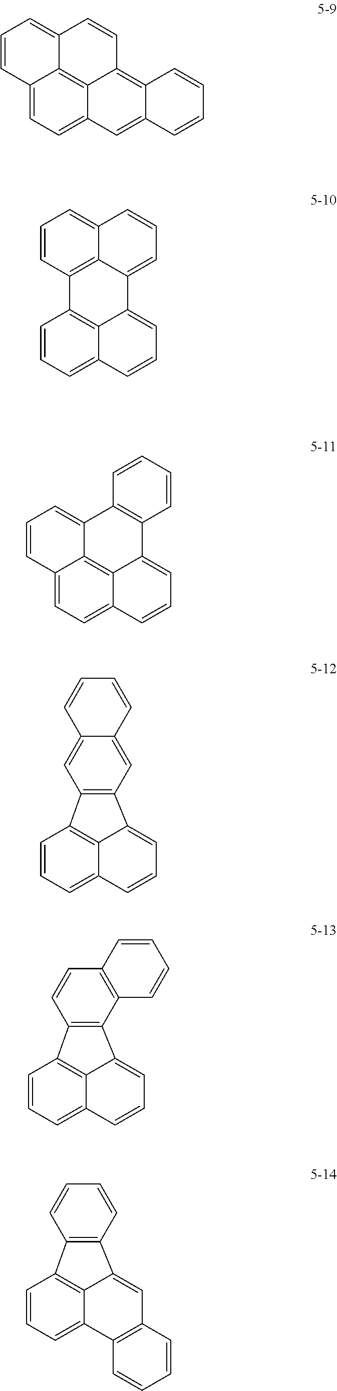 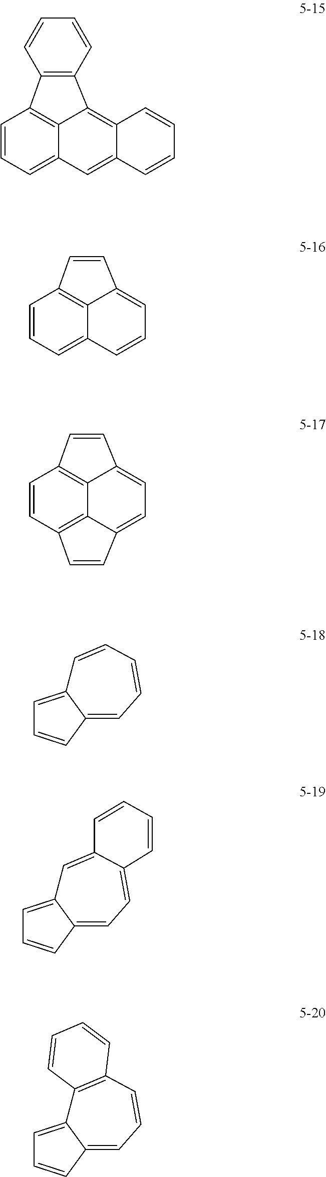 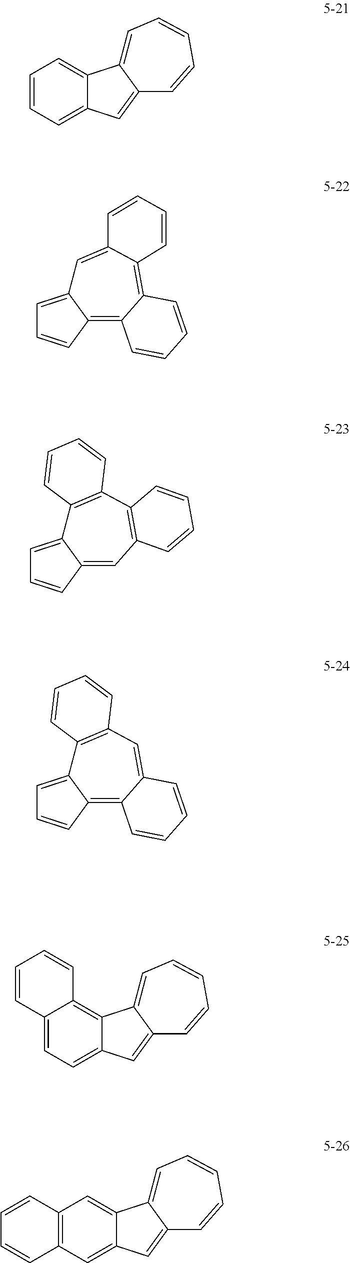
wherein in Formulae 5-1 to 5-26,
one carbon atom is bonded to O in Formula 3, and
the remaining carbon atoms are each optionally substituted with hydrogen, deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylate anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or a combination thereof.

8. The polymer of claim 1,
wherein X₃₁ is represented by any one of Formulae 6-1 to 6-10: 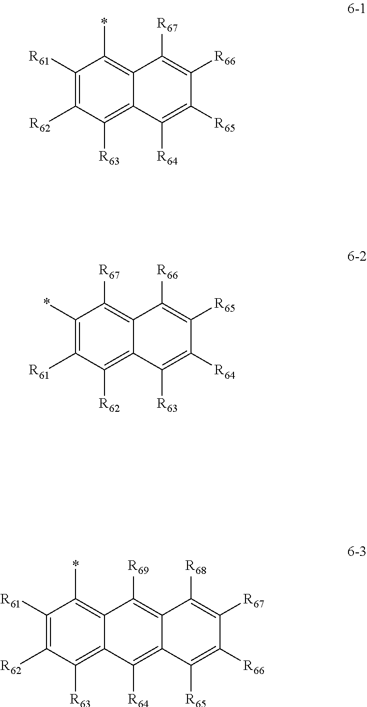 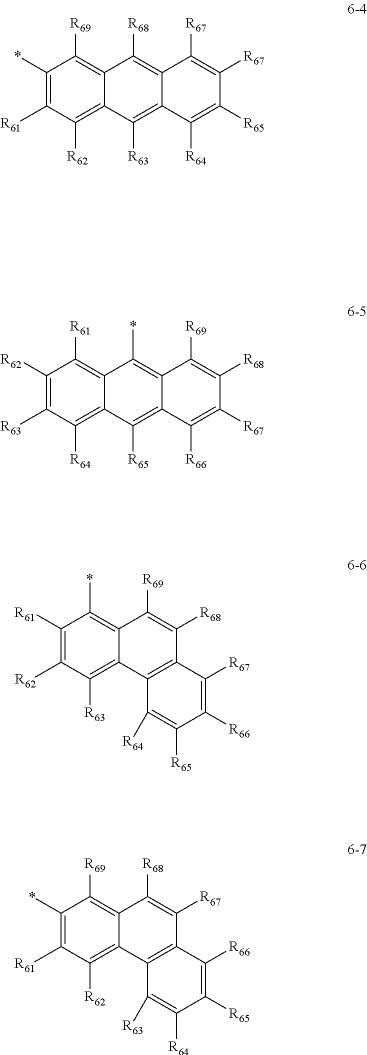 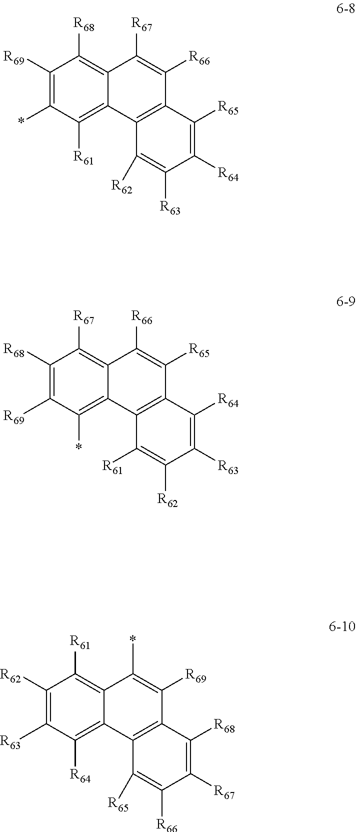
wherein in Formulae 6-1 to 6-10,
R₆₁ to R₆₉ are each independently selected from hydrogen, deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylate anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, and a C₆-C₂₀ aryl group, and
* is a binding site with O in Formula 3.

9. The polymer of claim 8,
wherein R₆₁ to R₆₉ are each independently selected from hydrogen, deuterium, a halogen atom, a hydroxyl group, a C₁-C₂₀ alkyl group, a C₁-C₂₀ halogenated alkyl group, and a C₁-C₂₀ alkoxy group.

10. The polymer of claim 1,
wherein R₁₁ to R₁₃, R₂₁, R₃₁, X₂₂ and X₃₂ are each independently selected from: hydrogen; deuterium; and a C₁-C₂₀ alkyl group, a C₃-C₂₀ cycloalkyl group and a C₆-C₂₀ aryl group, each unsubstituted or substituted with deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylate anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or a combination thereof.

11. The polymer of claim 1,
wherein the first repeating unit is selected from Group I,
the second repeating unit is selected from Group II, and
the third repeating unit is selected from Group III: 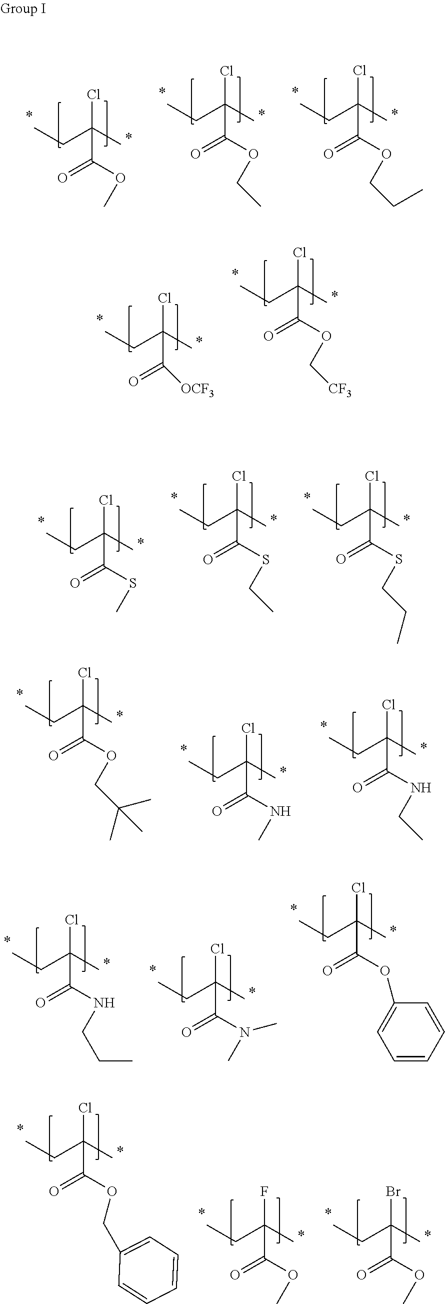 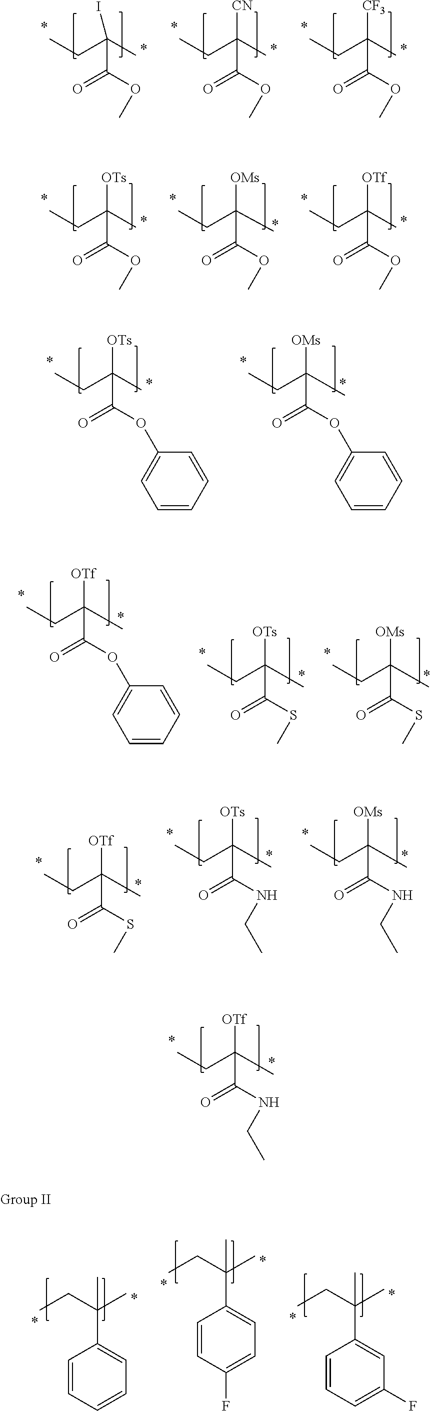 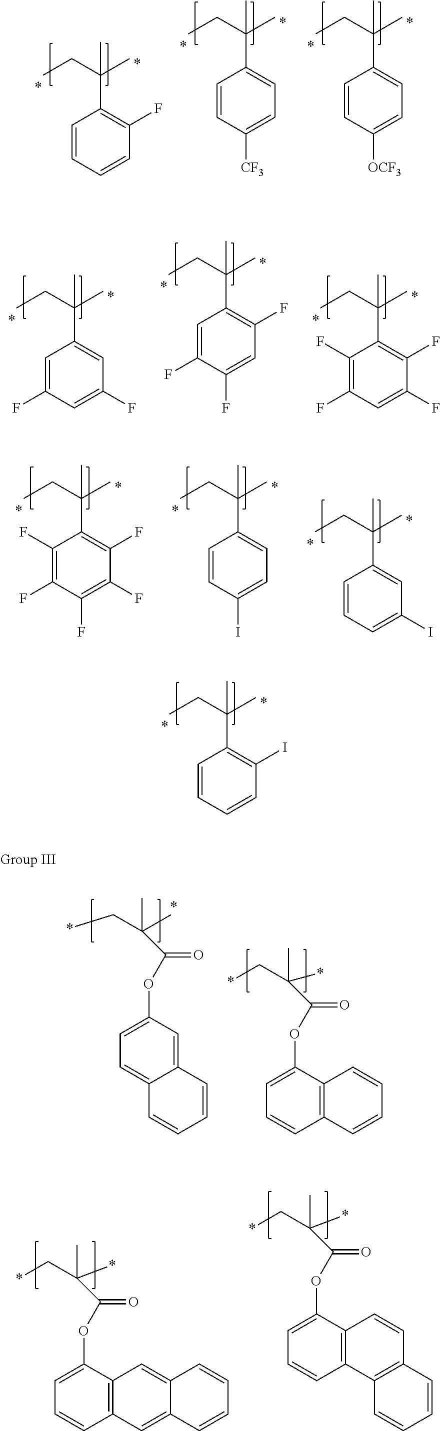 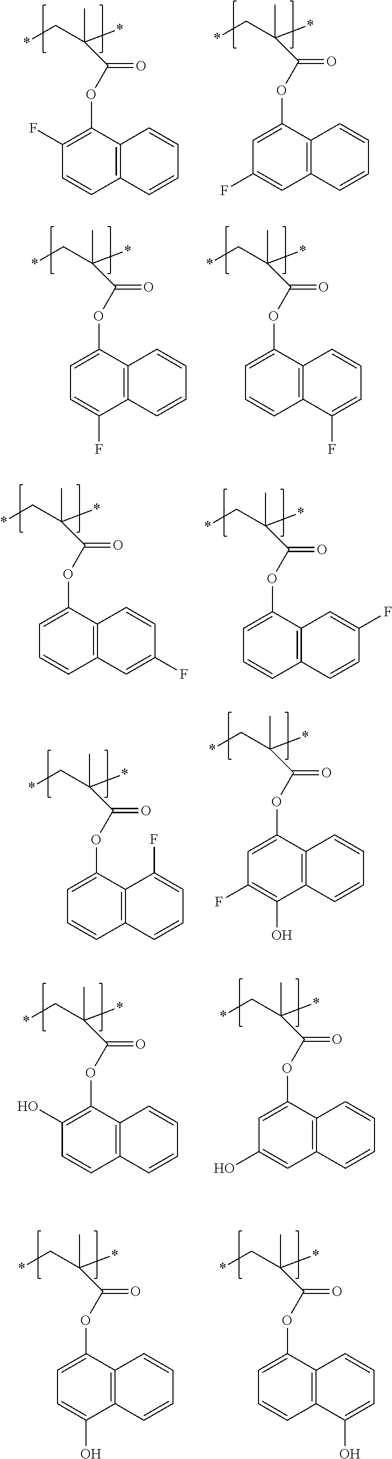 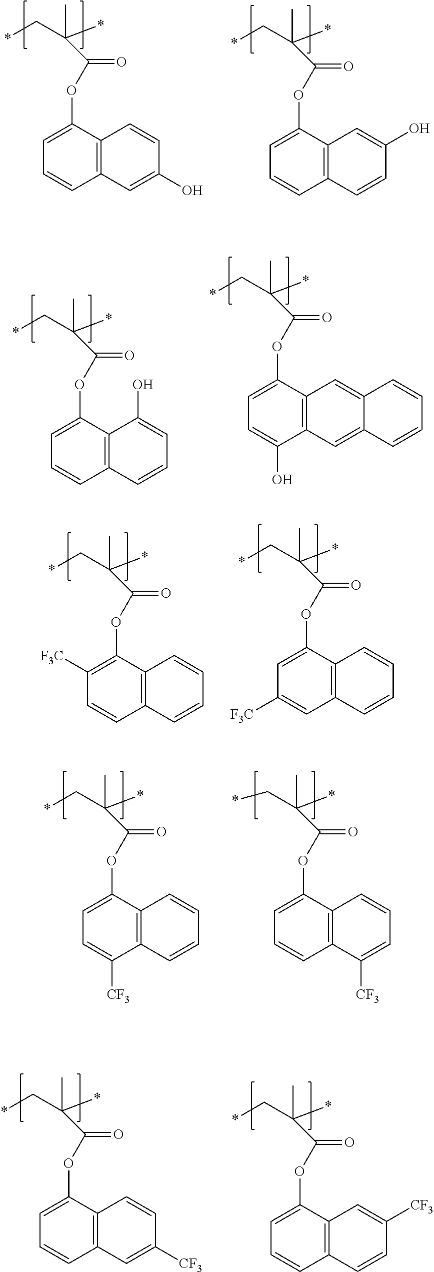 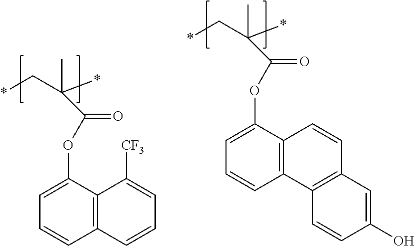 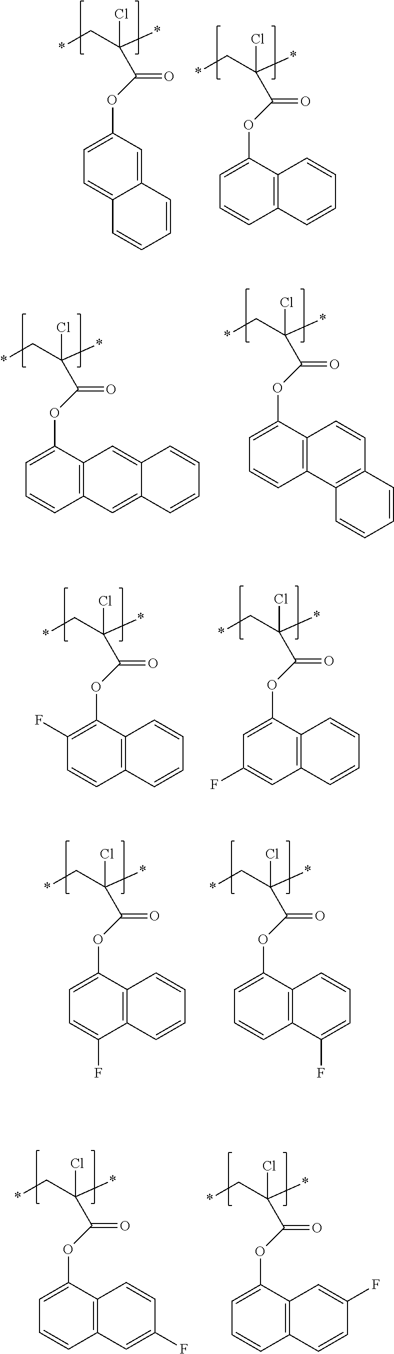 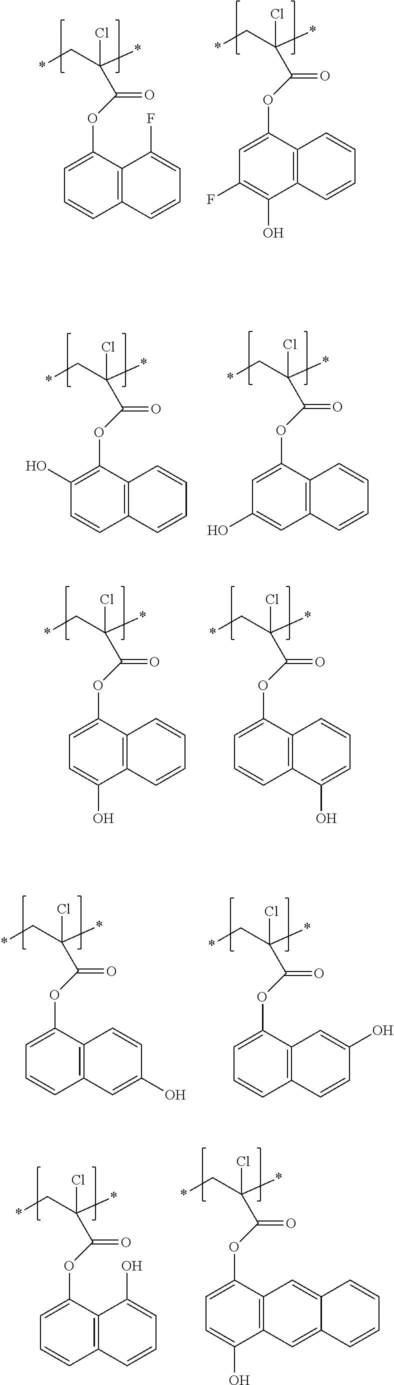 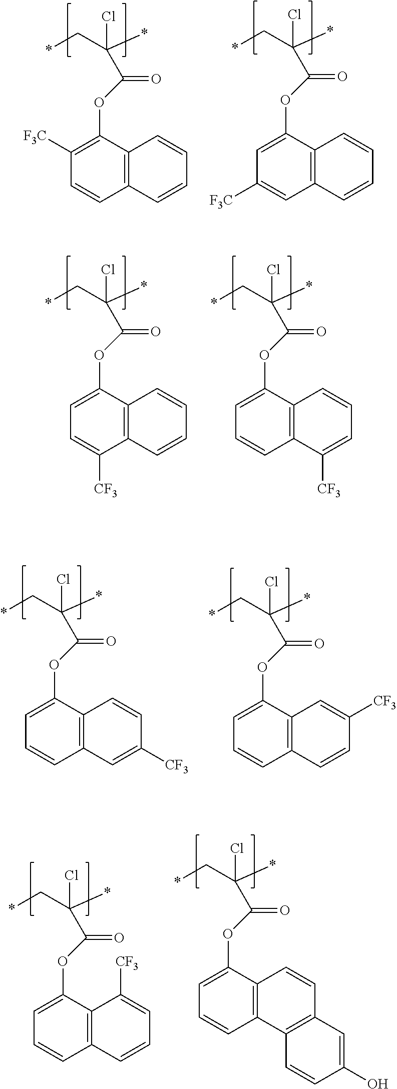
wherein in Groups I to III,
OMs is OSO₂CH₃, OTf is OSO₂CF₃, OTs is OSO₂C₆H₅(CH₃), and
* is a bonding site with a neighboring atom.

12. The polymer of claim 1,
wherein a molar ratio of the first repeating unit to the second repeating unit is in a range of about 5:1 to about 1:5, and
a molar ratio of the first repeating unit to the third repeating unit is in a range of about 10:1 to about 1:3.

13. A resist composition comprising:
the polymer of claim 1; and
a solvent.

14. The resist composition of claim 13,
wherein, other than the polymer, the resist composition substantially does not include a compound having a molecular weight of 1,000 or more.

15. The resist composition of claim 13,
wherein the resist composition substantially does not include a photoacid generator.

16. The resist composition of claim 13,
wherein the resist composition does not include an organometallic compound.

17. A method of forming a pattern, the method comprising:
applying the resist composition of claim 13 onto a substrate to form a resist film;
exposing at least a portion of the resist film to high-energy rays to provide an exposed resist film; and
developing the exposed resist film by using a developer.

18. The method of claim 17,
wherein the exposing is performed by at least one of irradiating ultraviolet rays, deep ultraviolet (DUV) rays, extreme ultraviolet (EUV) rays, X-rays, γ-rays, electron beams (EBs) or a particle beams.

19. The method of claim 17,
wherein a main chain of the polymer is decomposed by the exposing.

20. The method of claim 17,
wherein the exposed resist film includes an exposed portion and a non-exposed portion, and
wherein the exposed portion is removed in the developing.
